(19) United States
(12) Patent Application Publication
(10) Pub. No.: US 2017/0016114 A1
(43) Pub. Date: Jan. 19, 2017

(54) PLASMA ATOMIC LAYER DEPOSITION SYSTEM AND METHOD

(71) Applicant: Ultratech, Inc., San Jose, CA (US)

(72) Inventors: Jill S Becker, Cambridge, MA (US); Roger R Coutu, Hooksett, NH (US); Douwe J Monsma, Amsterdam (NL)

(21) Appl. No.: 15/277,096

(22) Filed: Sep. 27, 2016

Related U.S. Application Data
(62) Division of application No. 12/647,821, filed on Dec. 28, 2009.
(60) Provisional application No. 61/204,072, filed on Dec. 31, 2008.

(51) Int. Cl. C23C 16/455; C23C 16/458

(52) U.S. Cl. CPC C23C 16/45536; C23C 16/45544; C23C 16/45504; C23C 16/458

(57) ABSTRACT

A gas deposition chamber includes a volume expanding top portion and a substantially constant volume cylindrical middle portion and optionally a volume reducing lower portion. An aerodynamically shaped substrate support chuck is disposed inside the gas deposition chamber with a substrate support surface positioned in the cylindrical middle portion. The top portion reduces gas flow velocity, the aerodynamic shape of the substrate support chuck reduces drag and promotes laminar flow over the substrate support surface, and the lower portion increases gas flow velocity after the substrate support surface. The gas deposition chamber is configurable to 200 mm diameter semiconductor wafers using ALD and or PALD coating cycles. A coating method includes expanding process gases inside the deposition chamber prior to the process gas reaching a substrate surface. The method further includes compressing the process gases inside the deposition chamber after the process gas has flowed passed the substrate being coated.

### 1. RELATED APPLICATIONS

This application is a divisional of U.S. patent application Ser. No. 12/647,821, filed on Dec. 28, 2009, which claims priority to U.S. Provisional Application No. 61/204,072, filed Dec. 31, 2008, both of which are incorporated herein by reference in their entireties.

### 2. COPYRIGHT NOTICE

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice shall apply to this document: Copyright 2009, Cambridge NanoTech, Inc.

### 3. BACKGROUND OF THE INVENTION

### 3.1 Field of the Invention

The exemplary, illustrative, technology herein relates to plasma-assisted or plasma-enhanced atomic layer deposition (PALD) systems and operating methods thereof and to gas deposition or reaction chamber configurations configured to support a substrate being coated in a low eddy current regions by maintaining substantially laminar gas flow through the gas deposition or reaction chamber.

### 3.2 The Related Art

Gas or vapor deposition is a method of exposing a solid surface to a gas or vapor, hereinafter a gas, in order to deposit a material layer onto the solid surface. Various gas deposition methods are used in semiconductor processing in the fabrication of integrated circuits and the like. More generally, gas deposition is used to form thin films onto a wide range of solid substrates to modify the surface properties thereof. In practice, gas deposition methods are performed by placing a solid substrate into a gas deposition chamber, also referred to herein as a “reaction chamber”, and exposing the solid substrate to one or more gasses. The gasses react with exposed surfaces of the solid substrate to deposit or otherwise form a new material layer or thin film thereon. Generally, the new material layer is formed by a chemical reaction between one or more reactants introduced into the reaction chamber and surfaces of the substrate surface. Ideally, the reactants form atomic bonds with the substrate surfaces.

In atomic layer deposition (ALD), a material monolayer is deposited in two gas deposition steps, which each produce a sub-monolayer as a result of a chemical reaction between a gas precursor and exposed surfaces of a substrate disposed inside the gas deposition or reaction chamber. The ALD coating process is self-limiting in that once all of the available substrate surface reaction sites, e.g. molecules, have reacted with a molecule of the precursor gas, the reaction stops. Thereafter, excess precursor gas is purged from the chamber. A second precursor gas is then introduced into the chamber to produce a second sub-monolayer as a result of a chemical reaction between the second precursor gas and exposed surfaces of the substrate to complete the formation of a new thin film material monolayer onto the exposed substrate surfaces. The second precursor reaction is also self-limiting. Accordingly, the thin film monolayer formed by the two-step process has a substantially uniform and predictable material thickness that is substantially non-varying over exposed surfaces of the entire substrate, and depending upon cycle or exposure times, may even produce uniform coating thicknesses even over the surfaces of very high aspect ratio micron sized surface features such as holes. The second precursor reaction also creates a surface molecule that will react with the first precursor gas to form another sub-monolayer. Accordingly, the two-step ALD process can be repeated indefinitely to build up a desired material thickness layer comprising a plurality of monolayers formed onto the exposed surfaces.

Some advantages of the ALD process include precise monolayer thickness control and uniformity, relatively low process temperature windows, (e.g. less than 400° C.), low precursor gas consumption, high quality films, and precise total material thickness control which is governed by the number of monolayer coating cycles performed. Some of the disadvantages of the ALD process include a decrease in coating throughput because the ALD process requires two deposition cycles per monolayer, a limited number of ALD precursors, and therefore a limited number of materials that can be used to form thin films by the ALD process, and that the ALD reactants react with every surface that they are exposed to including the gas deposition or reaction chamber walls, gas flow conduits, pumps, valves and other surfaces that can be damaged over time by exposure to an extended number of ALD material coating cycles.

Recently, plasma assisted or plasma enhanced atomic layer deposition (PALD) methods have been disclosed to replace one of the ALD reactants with a reactive species from an O₂, N₂ or H₂ plasma. For example, instead of using a H₂O or NH₃ precursor gas, a suitable plasma may be introduced into the reactions chamber. In one disclosure entitled Opportunities for Plasma-Assisted Atomic Layer Deposition by Kessels et al. published in the ECS Trans 3 (2006)—Atomic Layer Deposition Applications 2, several advantages of PALD are listed including higher film densities with lower impurity levels and better control of film composition and microstructure, a reduction in the substrate temperature, an increased choice of precursors and coating materials, the ability to introduce dopants by co-doping during the plasma step, increased growth rates per cycle, fewer purging steps and the possibility for in situ substrate conditioning, plasma densification and nitridation.

Numerous engineering challenges exist that prevent rapid deployment and advancement of ALD and PALD coating systems. In particular, the need for a contaminate free environment inside the gas deposition or reaction chamber during each coating cycle generally requires that the chamber be purged with an inert gas and pumped to a deep vacuum pressure after each gas deposition cycle. This requires that the vacuum chamber be formed as a deep vacuum vessel and demands the use of expensive and difficult to maintain vacuum hardware and plumbing as well as numerous safety features and controls to monitor pressure and the state of various valves ports and other hardware to prevent damage to the equipment or harm to a human operator. In addition, the precursor gasses tend to be highly corrosive and potentially harmful to human operators and sometimes volatile when released into the local atmosphere and it is a difficult engineering challenge to contain and control the flow of precursor gasses at all times.

In addition, the ALD and PALD process require numerous heating steps to heat or excite the reactants, to heat the substrate being coated, to heat the gas deposition or reaction chamber walls and often to heat other components such as precursor input components and chamber outflow components, that may be exposed to the reactants or precursors. This requires numerous heating elements, extensive use of thermal insulation, numerous thermal sensors and other control and safety features operating to optimize the coating processes as well as to prevent damage to the equipment or to a human operator.

It is also a difficult engineering problem to filter or otherwise trap unused precursors that are being purged from or flowing out of the gas deposition or reaction chamber to prevent the reactants from contaminating other devices such as vacuum valves and pumps and to prevent reactants from escaping to the local atmosphere.

One example of a conventional thermal ALD system (100) is shown in FIG. 1. The system (100) comprises a system cabinet (130) that encloses various required sub-systems such as vacuum pumps, reactant and purge gas supply piping, sensors and control elements that support processing of round wafer substrates in a gas deposition chamber (110) that is vacuum-sealed by way of a closable lid (120). The system shown in FIG. 1 is configured for conventional atomic layer deposition, (ALD) and is usable to ALD coat one semiconductor wafer at a time. The system is commercially available from Cambridge Nanotech Inc. of Cambridge Mass. under the trade name SAVANNAH. Moreover, specific elements of the ALD system of FIG. 1 are disclosed in copending U.S. patent application Ser. No. 11/167,570, published as U.S. Patent Application Publication No. 2006-0021573, by Monsma et al. entitled VAPOR DEPOSITION SYSTEMS AND METHODS, filed on Jun. 27, 2005, which is incorporated herein by reference in its entirety.

As the advantages of ALD and PALD coating processes are further evaluated, the demand to develop more sophisticated and production oriented ALD and PALD coating systems is increasing. An important problem to be solved in the art is to reduce the duration of each gas deposition cycle, each purge cycle and or to reduce the number of gas deposition and purge cycles while still achieving the desired coating results. A further problem to be solved is to expand the versatility of ALD or PALD coating systems by configuring coating systems to be able to perform a variety of different coating types using a variety of different coating precursors and or plasma source gases as well as to operate at different process temperatures. Such improvements allow a user to use a single device for many different coating tasks to reduce the users overall capitol equipment investment. A still further problem to be solved is the need to integrate ALD and PALD equipment into existing semiconductor and other electronic device manufacturing facilities which tend to be highly automated and to require access to the gas deposition chamber from inside clean room environments as well as the ability to control the coating process from inside the clean room environment. In addition, as ALD and PALD systems are integrated into existing production environments there is a need for improved coating process controls, to improve automated safety features and automated coating cycle controls and provide automated substrate insertion and removal from the deposition chamber. In addition, there is a demand to reduce the footprint or floor space taken up by ALD and PALD coating systems as they are integrated into existing production environments.

### 4. BRIEF SUMMARY OF THE INVENTION

The present invention overcomes the problems cited in the prior art by providing a gas deposition chamber for depositing solid material layers onto substrates supported therein. The chamber includes an external chamber wall disposed along a longitudinal or vertical axis and formed to surround a hollow gas deposition volume. The volume is formed with a top portion that is continuously expanding and a middle portion that has a constant cylindrical volume. Both volumes are axially centered by the longitudinal axis. A top circular aperture axially centered by the longitudinal axis provides a top access into the volume expanding top portion. A plasma source flange is formed to surround the top circular aperture and a plasma source mounted on the plasma flange delivers charged and uncharged plasma gases through the top circular aperture.

The external chamber wall surrounding the volume expanding top portion may be formed to enclose a truncated one-sheet hyperboloid of revolution having a center axis coincident with the longitudinal axis and having a transverse axis coplanar with the top circular aperture. Alternately, the external chamber wall surrounding the volume expanding top portion may be formed with a constant radius (R) or may be formed as a truncated cone with an axial center coaxial with the longitudinal axis. Heating elements may disposed to heat the external chamber wall to a desired operating temperature and a layer of thermal insulation may be disposed over the heating elements.

In an alternate embodiment, the middle constant volume cylindrical portion may be formed by a narrow cylindrical ring portion and the external chamber wall may be shaped to form a volume reducing lower portion of the gas deposition chamber extending between the cylindrical ring portion to the bottom circular aperture. In this configuration the gas in the volume reducing lower portion is compressed in volume and its flow velocity increases to help evacuate the gas deposition chamber faster and reduce cycle time.

A substrate support chuck includes a circular substrate support surface. The substrate support surface is supported inside the constant volume cylindrical middle portion of the hollow gas deposition volume and is axially centered by and substantially orthogonal to the longitudinal axis. A bottom end of the external chamber wall forms a bottom aperture or exit aperture centered by the longitudinal axis. A diameter of the exit port is larger than a diameter of the substrate support surface so that the substrate support chuck can be installed through the exit port. A trap flange is provided surrounding the bottom circular aperture for attaching a trap assembly to the trap flange.

A load port aperture passes through the external chamber wall to the cylindrical middle portion and provides access through the external wall for loading a substrate onto the substrate support surface. A load port is attached to the external chamber wall surrounding the load port aperture and the load port may include manual or automated a load port gate. A movable load port aperture cover may be provided inside the load port to cover the load port aperture during gas deposition cycles. A purge port may also be provided to deliver an inter gas into the load port. A precursor input port passes through the external chamber wall proximate to the top circular aperture for delivering precursor gases and inert gases into the volume expanding top portion of the hollow gas deposition volume. The precursor port is directed at 45-degree angle with respect to the vertical axis.

The substrate support chuck includes a heating element disposed to heat the circular substrate support surface to a gas deposition temperature. The substrate support chuck includes an aerodynamically formed outer shell attached to the circular substrate support surface for reducing aerodynamic drag of the substrate support chuck. The outer shell may be formed as a hemispherical shell with an axial center that is substantially coaxial with the axial center of the circular substrate support surface, a parabolic shell, with a parabolic focus that is substantially coaxial with the axial center of the circular substrate support surface or a right circular cone with centered by the axial center of the circular substrate support surface. A circumferential edge of the circular substrate support surface may be radiused to further reduce aerodynamic drag of the substrate support chuck.

The substrate support chuck is preferably supported in the center of the middle portion of the hollow gas deposition volume by three hollow tubes that are fixedly attached to the outer shell and to a support structure such as the external chamber wall, the exit flange or a frame member. The hollow tubes had a low drag coefficient and provide a conduit extending from inside the outer shell to outside the external chamber wall for running wires to the heating element.

The substrate support chuck may include a movable substrate support element for lifting or separating a substrate from the substrate support surface and for supporting the substrate vertically separated from the substrate support surface during loading and unloading. The substrate support element is moved by a lifting mechanism housed inside the substrate support chuck and passing through the substrate support surface.

A trap assembly is attached to the trap flange for trapping selected components of outflow gases exiting through the bottom circular aperture. A vacuum pump is fluidly interconnected with an exit port of the trap assembly for drawing outflow gas from the hollow gas deposition chamber through the trap assembly. A stop valve may be disposed between the vacuum pump and the trap assembly.

The present invention further overcomes the problems cited in the prior art by providing a method for coating a substrate with a solid material layer. The method includes supporting the substrate on substrate support surface disposed in a substantially constant volume middle portion of a hollow gas deposition volume. Thereafter a first process gas such as precursor gas or a charged or uncharged plasma gas is introduced into a volume expanding top portion of the hollow gas deposition volume and allowed to expand in volume prior to impinging surfaces of the substrate. After the flow of the first process gas is stopped, the first process gas is drawn out of the hollow deposition chamber through an exit port formed by the bottom the constant volume middle portion until while a flow of inert gas is delivered into the hollow gas deposition volume.

Thereafter a second process gas such as precursor gas or a charged or uncharged plasma gas introduced into the volume expanding top portion of the hollow gas deposition volume and allowing to expand in volume prior to impinging surfaces of the substrate. Then the second process gas is removed from the hollow gas deposition volume while delivering an flow of inert gas into the hollow gas deposition volume. The method may further include the step of reducing the volume of each of the first and the second process gasses after they have flowed past the substrate support surface toward the exit port.

### 5. BRIEF DESCRIPTION OF THE DRAWINGS

The features of the present invention will best be understood from a detailed description of the invention and a preferred embodiment thereof selected for the purposes of illustration and shown in the accompanying drawings in which:

FIG. 1 depicts an orthogonal view of one example of a prior art ALD system for ALD coating circular semiconductor wafer substrates.

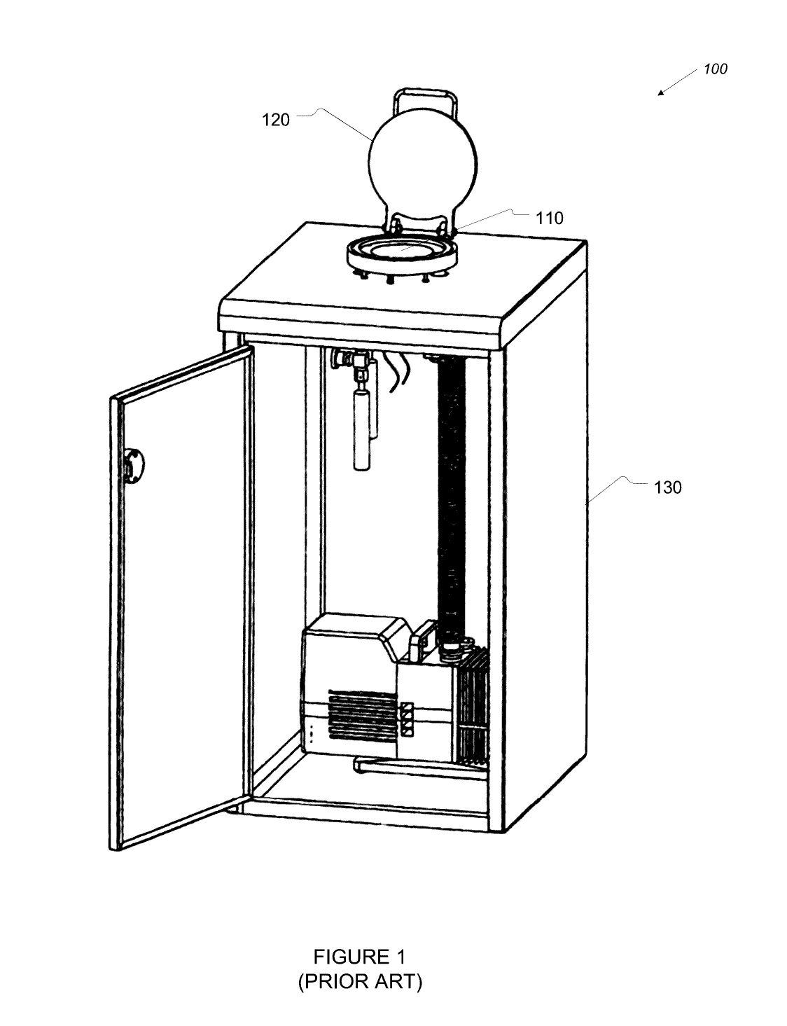

FIG. 2 depicts a side view of an exemplary PALD system with a load lock chamber and substrate transport mechanism according to the present invention.

FIG. 3 depicts a close-up side view of the gas deposition chamber and load lock chamber of the exemplary PALD system of the present invention.

FIG. 4 depicts a translucent isometric view of the gas deposition chamber and load lock chamber with a wafer substrate shown positioned on a substrate holder inside a load lock chamber of the exemplary PALD system of the present invention.

FIG. 5 depicts a translucent isometric view of the gas deposition chamber and load lock chamber with a wafer substrate shown positioned on the substrate holder and centered over a heated wafer chuck inside the gas deposition chamber of the exemplary PALD system of the present invention.

FIG. 6 depicts a side cut-away view of an exemplary PALD configured gas deposition chamber and related input and output ports according to the present invention.

FIG. 7 depicts a side cut-away view of an exemplary heated substrate support chuck according to the present invention.

FIG. 8 depicts an isometric view of an alternate embodiment of the gas deposition chamber according to the present invention.

FIG. 9 depicts side and isometric views of a graphical representation of a computer-generated model to illustrate gas flow direction and velocity as a function of position inside an exemplary gas deposition chamber of the present invention.

FIG. 10 depicts a schematic diagram of an exemplary vacuum system of the present invention.

FIG. 11 depicts a schematic diagram of an exemplary input gas supply system of the present invention.

FIG. 12 depicts an isometric view of an exemplary gas deposition system configuration with a spherical load lock chamber and a tall gas cabinet according to the present invention.

FIG. 13 depicts an isometric view of an exemplary gas deposition system configuration with a manual load port and a tall gas cabinet according to the present invention.

FIG. 14 depicts an isometric view of an exemplary gas deposition system configuration with a manual load port a short gas cabinet and a side mounted controller and user interface according to the present invention.

FIG. 15 depicts an isometric view of an exemplary front manual load system configuration with a short gas cabinet and a front mounted controller and user interface according to the present invention.

FIG. 16 depicts an isometric view of an exemplary cluster configured gas deposition system with a short gas cabinet and rear mounted controller and user interface according to the present invention.

FIG. 17 depicts an isometric view of an exemplary gas deposition system configuration with dual manual load gas deposition chambers, as short gas cabinet and side mounted controller and user interface according to the present invention.

FIG. 18 depicts an isometric view of an exemplary “zero footprint” gas deposition system configuration with dual gas deposition chambers, dual user interface controls inside a clean room and a service interface outside the clean room according to the present invention.

FIG. 19 depicts an isometric view of an alternate embodiment of a gas deposition chamber formed with a top mounting rectangular load lock chamber and substrate transport mechanism according to the present invention.

FIG. 20 depicts a side section view of an alternate embodiment of a gas deposition chamber configured with a movable substrate support element and load port aperture cover suitable for automated substrate loading and unloading according to the present invention.

FIG. 21 depicts a side section view of a substrate support chuck configured with a movable substrate support element suitable for automated substrate loading and unloading according to the present invention.

FIG. 22 depicts a cutaway isometric view of an alternate embodiment of a gas deposition chamber configured with a movable substrate support element and load port aperture cover suitable for automated substrate loading and unloading according to the present invention.

### 6. LISTING OF ITEM NUMBERS

| | |
|---|---|
| 100 | Conventional thermal ALD system |
| 110 | Gas deposition chamber |
| 120 | Closable lid |
| 130 | System cabinet |
| 1000 | Load lock Configuration |
| 1010 | Plasma Source |
| 1020 | Gas cabinet |
| 1030 | Precursor Port |
| 1040 | Reaction (or Gas Deposition) Chamber |
| 1050 | Load Port |
| 1060 | Gate Valve |
| 1070 | Load lock chamber |
| 1080 | Transport Arm |
| 1090 | Isolation Valve |
| 1100 | Turbo Vacuum Pump |
| 1110 | Mag-Lev Turbo Vacuum Pump |
| 1120 | Roughing Vacuum Pump |
| 1130 | System Control Module |
| 1140 | Transport Mechanism |
| 1150 | Isolation Valve |
| 1160 | Pressure Gauge |
| 1190 | Top Vent |
| 1200 | Trap Assembly |
| 2010 | Plasma gas Port |
| 2070 | Substrate Holder |
| 2080 | Heated Chuck |
| 2100 | Plasma source flange |
| 2140 | Purge gas conduit |
| 2150 | Purge gas conduit |
| 2160 | Plasma port |
| 3010 | Load port aperture |
| 3020 | Load lock gate |
| 3035 | Circular Flange |
| 3045 | Transport Arm Inner Rod |
| 3050 | Transport Arm Outer Casing |
| 3055 | Load port aperture |
| 3060 | Load Port Shield |
| 3070 | Exit port) |
| 5000 | Gas Deposition Chamber |
| 5010 | Pressure Gauge |
| 5015 | Exit port |
| 5020 | Trap assembly |
| 5025 | Isolation valve |
| 5030 | Conical portion |
| 5060 | Trap exit port |
| 5080 | Hollow gas deposition volume |
| 5090 | Heated Chuck |
| 5100 | Precursor Gas Port |
| 5105 | External chamber wall |
| 5110 | Plasma exciter tube |
| 5115 | Cylindrical middle portion |
| 5120 | Plasma Source |
| 5125 | Top circular aperture |
| 5130 | Plasma source flange |
| 5135 | Substrate load aperture |
| 5140 | Manual load Port |
| 5145 | Load port gate |
| 5155 | Opposing circular flanges |
| 5165 | Radial axis |
| 5175 | Purge Gas Conduit |
| 6010 | Heating coils |
| 6015 | Substrate support surface |
| 6020 | reflective thermal baffles |
| 6050 | Circular top plate |
| 6090 | Hemispherical Outer shell |
| 6100 | Hollow tubes |
| 7020 | Top aperture |
| 7030 | Precursor Gas Port |
| 7080 | Hyperboloid mid-portion |
| 7085 | volume reducing lower portion |
| 7090 | Substrate support chuck |
| 7095 | Bottom circular aperture |
| 8000 | Gas deposition chamber second embodiment |
| 8100 | Precursor port |
| 8105 | Top portion |
| 8110 | Cylindrical ring middle portion |
| 8115 | Lower portion |
| 8130 | Plasma source flange |
| 8140 | Load port |
| 8145 | Substrate load port |
| 8155 | Trap flange |
| 8160 | Bottom circular aperture |
| 8170 | Vent tube |
| 10000 | Vacuum system schematic |
| 9010 | Vacuum gauge |
| 9020 | Pump exhaust |
| 9030 | Load lock purge port |
| 9040 | Pump purge |
| 9050 | Soft start valve |
| 11000 | Input gas panel schematic |
| 12000 | Front load lock configuration |
| 13000 | Front load tall gas cabinet configuration |
| 13100 | Manual load port |
| 13110 | Deposition chamber |
| 14000 | Front load side control configuration |
| 14100 | System controls |
| 15000 | Front load front control configuration |
| 15100 | Controller |
| 16000 | Cluster configuration |
| 16100 | Side Mounted Controller |
| 16110 | Load port |
| 16120 | Load lock port with gate valve |
| 17000 | Dual reaction chamber side controller configuration |
| 17100 | Side controller |
| 17110 | Load port gate |
| 18000 | Dual reaction chamber dual controller configuration |
| 18010 | Maintenance station display |
| 18020 | Operator station controls |
| 18030 | Operator station displays |
| 18040 | Maintenance station controls |
| 18050 | Emergency Shutoff Control |
| 19000 | System |
| 19100 | Load chamber |
| 19110 | Top access load port gate |
| 19120 | Back hinges |
| 19130 | Transport arm |
| 20000 | Gas deposition chamber |
| 20005 | Deposition chamber |
| 20100 | Outer wall |
| 20110 | Hollow deposition chamber |
| 20115 | Rectangular input aperture |
| 20120 | Plasma source flange |
| 20130 | Trap assembly flange |
| 20140 | Load port |
| 20150 | Load port aperture |
| 20160 | End flange |
| 20170 | Movable load port aperture cover |
| 20180 | Shuttle mechanism |
| 20185 | Purge line and valve |
| 20190 | Link |
| 21000 | Substrate support chuck |
| 21100 | Circular substrate support surface |
| 21110 | Hemispherical bottom portion |
| 21120 | Radius |
| 21130 | Substrate support lifting mechanism |
| 21140 | Substrate support element |
| 21140 | Brackets |
| 21145 | Top circular plate |
| 21150 | Circular substrate support element |
| 21160 | Circular recess |
| 21170 | Lift pins |
| 21180 | Lift plate |
| 21200 | Bottom wall of chamber housing |
| 21210 | Actuator plunger |
| 21220 | Transfer bracket |
| 21230 | Actuator |
| 21240 | Bellows |
| 21270 | Stationary rods |

### 7. DESCRIPTION OF SOME EMBODIMENTS OF THE INVENTION

### 7.1 Overview

The present invention is a gas deposition system configured to deposit thin films onto substrate surfaces by several gas deposition processes. In particular, the gas deposition system of the present invention is configured as a plasma assisted or plasma enhanced atomic layer deposition (PALD) system, which includes a plasma source. The plasma source is suitable for delivering a plurality of different plasma excited gases into a gas deposition or reaction chamber. In addition, the gas deposition system of the present invention is configured as a conventional atomic layer deposition (ALD) system suitable for delivering a plurality of different ALD precursors or reactants into the gas deposition or reaction chamber. One advantage of the PALD aspect of the present invention is that a PALD gas deposition system can be used to deposit thin film material types that are not able to be deposited by the conventional or thermal ALD process and therefore not able to be deposited by conventional ALD coating systems.

In the exemplary embodiments described below, the gas deposition systems are configured to coat a top surface and side edge of a single circular semiconductor wafer up to 200 mm in diameter; however, several aspects of the present invention are independent of the type of substrate being coated. While the exemplary gas deposition systems described herein are configured to coat circular flat semiconductor substrates one at a time, various aspects of the present invention are independent of the shape or material of the substrate. In particular, the present invention uses a method of reducing the velocity of process gases delivered into the gas deposition chamber by expanding the volume of the process gases prior to the process gasses coming into contact with the surfaces being coated and these methods is usable in other gas deposition system configurations. Additionally, because the systems of the present invention utilize ALD and PALD coating processes, the present invention is capable of applying uniform coating layers to substantially flat surfaces as well as to complex shapes including those with micron scale high aspect ratio topographic features. Accordingly, the systems of the present invention are usable to coat three dimensional substrates such as formed metallic, plastic or ceramic elements including surgical tools, engine parts, electrical components and any other three dimensional element having surfaces to be coated as may be required. Moreover, the systems of the present invention, as described herein, allow every surface of the substrate that is exposed to deposition gases to be coated with a substantially uniform thin film layer thickness.

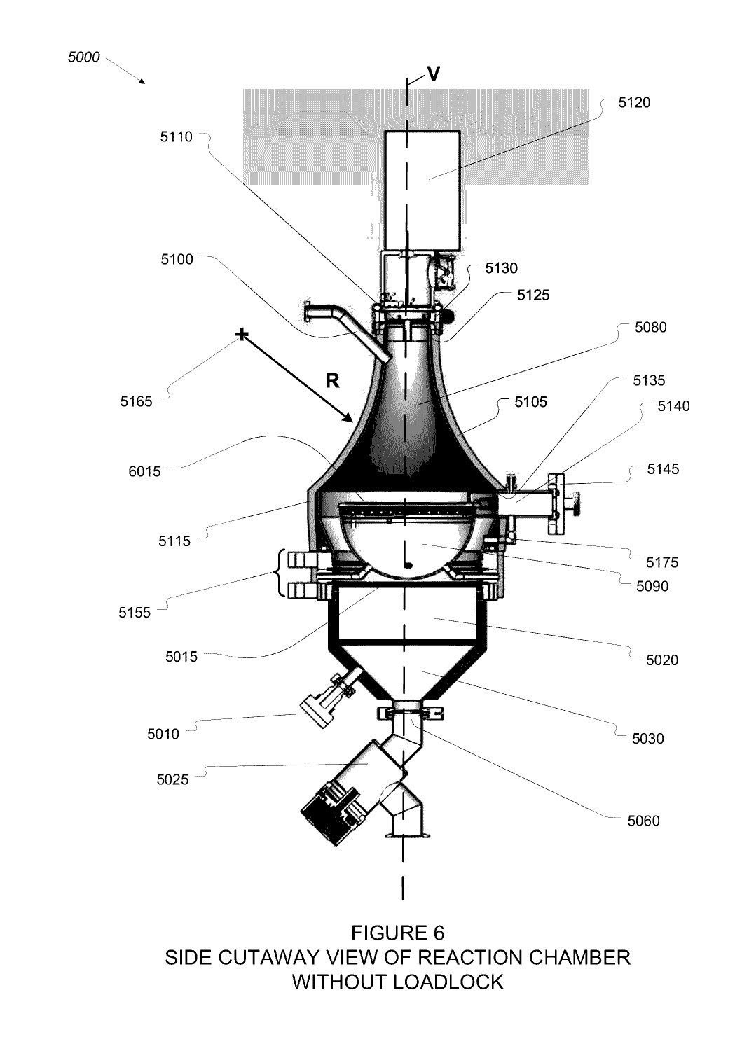

Several improvements of the system of the present invention as compared to conventional gas deposition systems relate to the shape of a gas deposition or reaction chamber shown in side cut away view in FIG. 6. In particular, the enclosure walls are shaped with a narrow top aperture that delivers input gases into a volume expanding top portion. The volume expanding top portion increase gas volume and reduces gas flow velocity prior to the input gases reaching the substrate being coated. In addition, the enclosure walls form a circular exit aperture that is large in diameter that the diameter of the largest substrates being coated and is large enough to receive the substrate support chuck through the circular exit aperture. In addition, the shape of the support chuck and the shape of the deposition chamber surrounding the substrate support chuck are optimized using computer flow modeling to reduce aerodynamic drag of the substrate support chuck. The net result is that the shape of the reaction chamber and support chuck contributes to substantially laminar gas flow through the reaction chamber. As will be described below, by maintaining a substantially laminar gas flow within the deposition chamber and especially by suppressing eddy current formation proximate to the substrate coating surfaces, coating uniformity on the substrate surfaces is improved, deposition and purge cycle times and process gas consumption are reduced.

Other improvements of the of the system of the present invention as compared to conventional gas deposition systems relate to the versatility of the manner in which gas combinations can be delivered into the gas deposition chamber to perform either conventional thermal ALD coating processes or plasma assisted or PALD coating processes. In addition, the system of the present invention can also perform chemical vapor deposition (CVD) coating process cycles by injecting at least two gases into the chamber simultaneously.

These and other aspects and advantages will become apparent when the description below is read in conjunction with the accompanying drawings.

### 7.2 Exemplary System Architecture

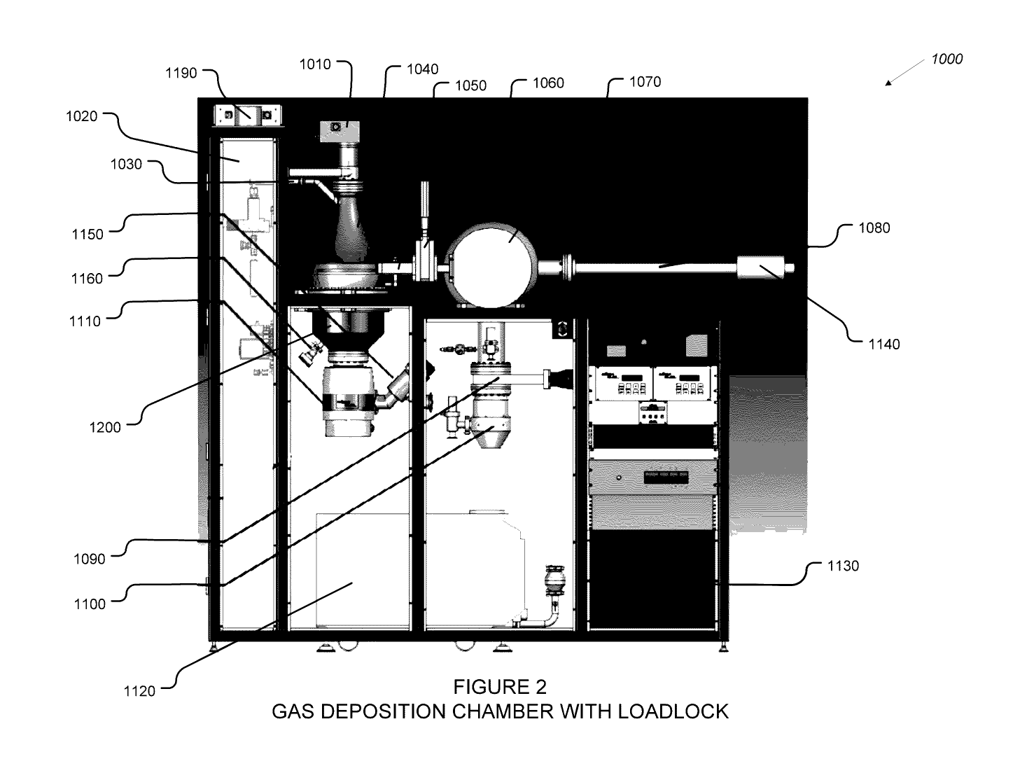

FIGS. 2-5 depict an exemplary implementation of a gas deposition system of the invention (1000), referred to herein as the “load lock configuration”. A substrate to be coated or otherwise processed enters the system through a load port aperture (3010) passing into a spherical load lock chamber (1070), which is a vacuum chamber. The load lock chamber (1070) is connected with a gas deposition or reaction chamber (1040) by a load port (1050). The gas deposition chamber (1040) is also a vacuum chamber and it is desirable to maintain the gas deposition chamber at a vacuum pressure during substrate loading and unloading cycles. Atmosphere is removed from the load lock chamber (1070) by opening a turbo gate valve or isolation valve (1090) and pumping the load lock chamber (1070) to a vacuum pressure using a conventional roughing vacuum pump (1120). Once a roughing vacuum pressure is achieved in the load lock chamber (1070), a conventional ceramic bearing turbo vacuum pump (1100) may be activated to further reduce the pressure of the load lock chamber (1070) to match the pressure of the gas deposition chamber (1040). The turbo gate valve (1090) may be closed to isolate the load lock chamber (1070) once the load lock chamber (1070) reaches the desired vacuum pressure.

A substrate to be coated or otherwise processed is loaded through the load port aperture (3010) onto a substrate holder (2070) which is initially stationed inside the load lock chamber (1070). The substrate holder (2070) is fixedly attached to a transport arm (1080) and movable from the load lock chamber (1070) into the gas deposition chamber (1040) by linear movement of the transport arm (1080). The transport arm (1080) is moved along a linear axis from the load lock chamber to the gas deposition chamber by a magnetic transducer (1140). Other means of actuating the transport arm, such as linear induction motors, hydraulic pistons, pneumatic rams, or the like, including a manual transport mechanism are also usable without deviating from the present invention. In addition, the transport arm (1080) and transducer (1140) are configured to lower the substrate holder into contact with a heated chuck once the substrate holder and substrate supported thereon are positioned in a coating position inside the gas deposition chamber. The lowering action and subsequent raising of the substrate holder to remove the substrate may be provided by lowering and raising the transducer (1140).

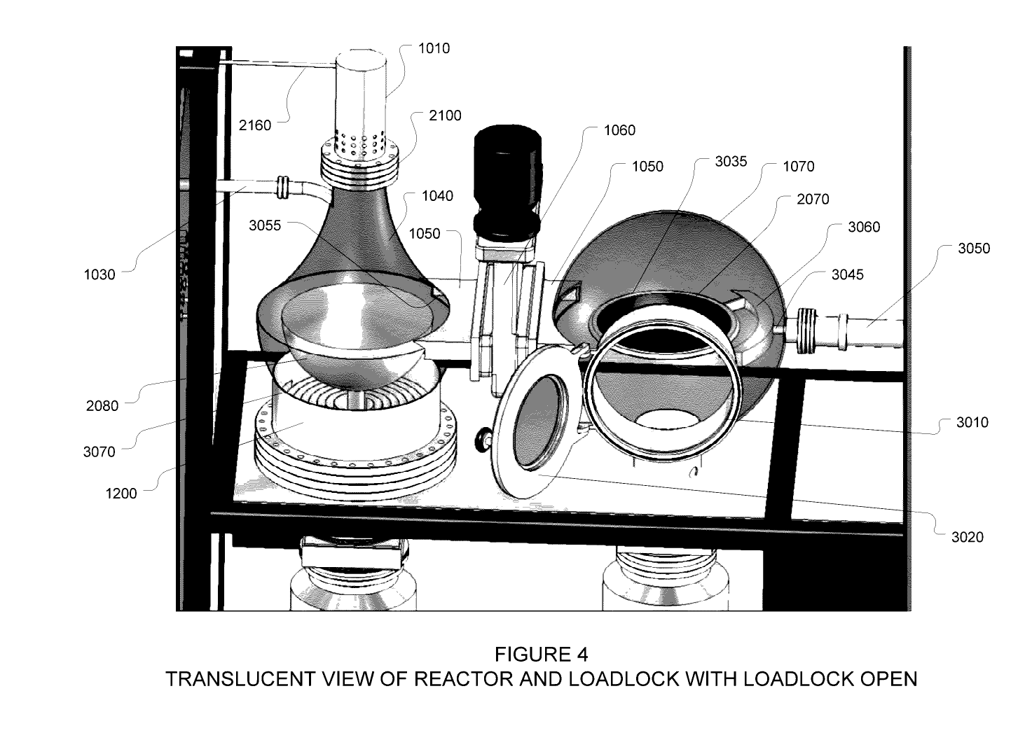

The load lock chamber (1070) and the gas deposition chamber (1040) are interconnected through a load port (1050). The load port (1050) comprises a rectangular conduit that extends between the spherical load lock chamber (1070) and the reaction chamber (1040). The load port (1050) is sized to pass a substrate supported on the substrate holder (2070) from the load lock chamber (1070) to the reaction chamber (1040). A gate valve (1060) is disposed in the load port (1050) between the load lock chamber (1070) and gas deposition chamber (1040). The gate valve (1060) serves to isolate the reaction chamber (1040) from the load lock chamber (1070). This prevents contaminates from entering the reaction chamber (1040) when the load lock chamber is open to the atmosphere. The closed gate valve (1060) is also used to maintain a vacuum pressure in the reaction chamber (1040) while the load lock chamber is opened to atmosphere while substrates are being loaded into or unloaded from the load lock chamber (1070). The transport arm (1080) moves the substrate holder (2070) and the substrate held thereon from the load lock chamber to the deposition chamber and positions the substrate is in a coating position within the gas deposition chamber (1040). As best viewed in FIG. 4, the subtract holder (2070) is formed with a load port shield (3060) attached thereto for contacting an outside surface of the gas deposition chamber (1040) when the substrate is in the coating position. The load port shield (3060) is configured to prevent precursor gasses from escaping from the gas deposition chamber (1040) during coating cycles. In addition, inert gas is pumped into the load port (1050) to provide a positive pressure gradient between the load port shield (3060) and the gas deposition chamber (1040) to further prevent precursor gasses from escaping from the gas deposition chamber (1040). Once the substrate is in the coating position within the gas deposition chamber (1040), the substrate is heated to the desired temperature for processing and a gas deposition coating process or other substrate processing is carried out.

The gas deposition chamber (1040) comprises a chamber enclosure wall, described below, formed to enclose a hollow gas deposition chamber which is sized to receive substrates to be coated or processed therein and which is constructed as a chamber suitable for deep vacuum pump down. The gas deposition chamber (1040) includes four ports passing through the chamber enclosure wall. A plasma source flange (2100) is formed at a narrow top end of the gas deposition chamber (1040) and a plasma source (1010) or other high-energy input source is attached to the plasma source flange (2100) for delivering plasma gases into the gas deposition chamber (1040). A plasma port (2160) delivers plasma gases to the plasma source (1010) and the plasma port interfaces with a plasma exciter tube (5110) which excites the plasma gases passing there through and delivers the plasma gases into the gas deposition chamber (1040) through the plasma source flange (2100). A second port comprises a precursor port (1030) passing through the narrow top end of the gas deposition chamber (1040) for delivering precursor gases into the gas deposition chamber proximate to the plasma source flange (2100). The plasma port (2160) and the precursor port (1030) are both in fluid communication with a gas panel, which is housed inside a gas tight cabinet (1020) that includes a top vent (1190) for venting the gas cabinet to a safe venting area. A third port passing through the gas deposition chamber enclosure comprises a rectangular load port aperture (3055). The rectangular load port aperture (3055) is sized and shaped as required to transport the substrate holder (2070) and a substrate to be coated there through. A fourth port passing through the gas deposition chamber enclosure comprises an exit port formed by a circular aperture (3070) at a wider base portion of the gas deposition chamber (1040). The exit port (3070) interfaces with an ALD type trap assembly (1200) that attaches to the base of the gas deposition chamber (1040). The ALD type trap assembly (1200) is heated and reacts with precursor and or plasma gases in gas outflow exiting from the gas deposition chamber (1040) to remove any remaining precursor and or plasma gases from the outflow to thereby prevent precursor and or plasma gas contamination of down stream vacuum system elements. The trap assembly (1200) also supports a vacuum pressure gauge (1160) for monitoring the gas pressure in the trap assembly. The gas deposition chamber (1040) may also include other ports such as additional precursor ports, purge gas ports, gauge ports, electrical interface ports, and the like, as may be required. Each of the gas deposition chamber ports is constructed with high performance vacuum seals and other hardware as required to prevent precursor gases from leaking out or atmosphere from leaking in when the reaction chamber is drawn down to a deep vacuum. Accordingly, it is advantageous to limit the number of ports in the reaction chamber.

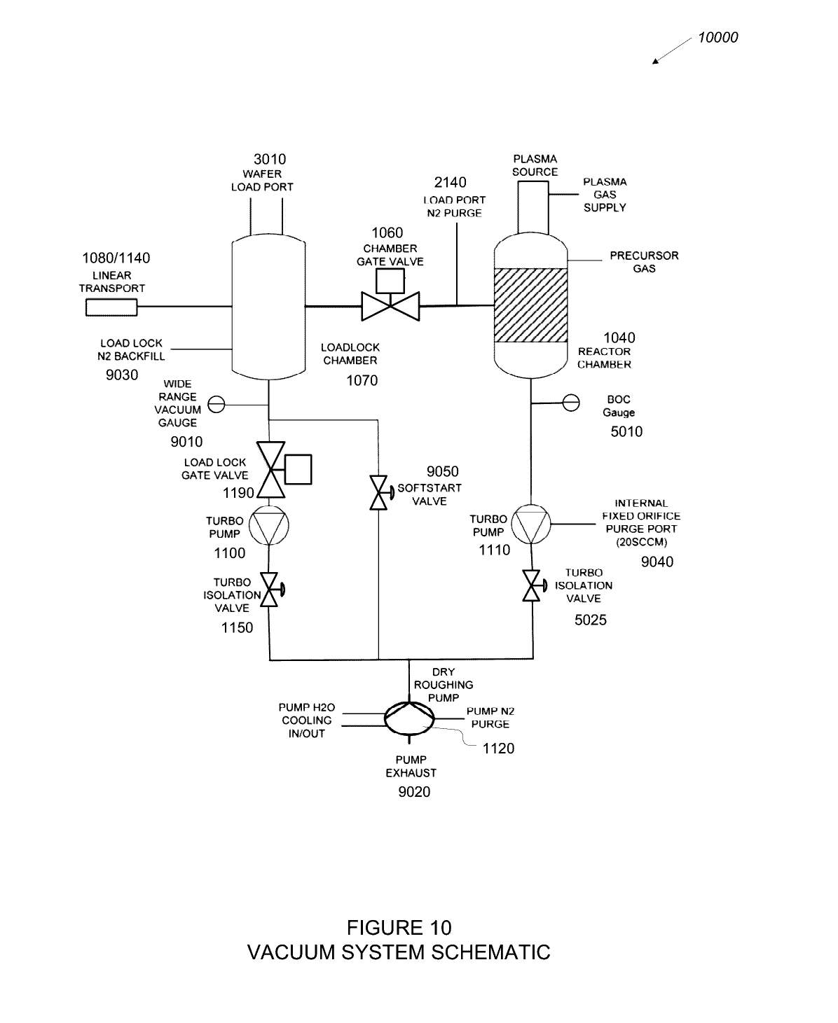

Generally, the gas deposition chamber of the load lock configuration (1000) is continuously maintained at a low vacuum pressure during operation and during substrate loading and unloading through the load port (1050). At start up, the roughing vacuum pump (1120) is used to draw the gas deposition chamber (1040) from atmospheric pressure down to less than 1 torr. Thereafter a magnetic bearing or (mag-lev) turbo vacuum pump (1110) is used to draw the gas deposition chamber (1040) down to an operating pressure, e.g. less than 100 μtorr. The gate valve (1060) serves to isolate the gas deposition chamber (1040) from the load lock chamber (1070). For example, the gate valve (1060) is closed before the load lock chamber is purged to atmospheric pressure for loading or unloading a substrate into the load lock chamber. This feature of the load locked gas deposition system (1000) is particularly advantageous because it reduces gas deposition cycle times. In particular, because the gas deposition chamber (1040) is isolated from the load lock chamber by the gate valve (1060), the deposition chamber (1040) remains at a vacuum pressure, e.g. less than 1 ton, during substrate load and unload cycles. This eliminates the need to use the roughing pump (1120) after each substrate is loaded into the deposition chamber (1040). Instead, each time a substrate is loaded into the gas deposition chamber (1040) or each time the gas deposition chamber is purged to remove a precursor gas between coating deposition cycles, the vacuum pressure in the gas deposition chamber can be pumped down using only the magnetic bearing or (mag-lev) turbo vacuum pump (1110). This makes the gas deposition chamber (1040) pump down a smaller adjustment to its vacuum pressure than would have to be made if the deposition chamber was exposed to the atmosphere. The small adjustments to the vacuum pressure inside the reaction chamber (1040) e.g. from less than 1 ton to less than 100 μtorr are shorter in duration as compared to pumping the deposition chamber down from atmospheric pressure. Thus, the load lock configuration (1000) can reduce the time required to coat each substrate by several minutes. In addition, the magnetic bearings of the turbo pump (1110) are used to gain increased pump velocity which is needed to produce lower vacuum pressures, e.g. down to less than 1 microtorr. As further shown in FIGS. 2 and 10, a stop or isolation valve (1150) is disposed between the gas deposition chamber (1040) and the roughing pump (1120) to isolate or gas seal the gas deposition chamber (1040) as required. This prevents precursors from inadvertently reaching the roughing pump, allows the deposition chamber to be isolated from the roughing pump (1120) to achieve deeper vacuum pressures using the magnetic bearing turbo pump (1110) and allows the roughing pump to be used to independently pump down the load lock chamber (1070.

Referring to FIGS. 2-4, the example load lock system (1000) includes a spherical load lock chamber (1070) configured with a load lock gate or door (3020). However, other load lock chamber shapes are usable without deviating from the present invention. A system electronic control module (1130) includes computer processing, power distribution, operator interface, communications, and various other electrical control systems as may be required to control all operations of the system (1000). The operations may include selecting coating processes, setting precursor and plasma gas mass flow rates and or gas volumes, selecting the number of deposition cycles, setting desired vacuum pressures, setting various temperatures of the substrate, the precursors, the chamber walls, the trap and other elements, measuring and tracking system performance, collecting data, communicating with external devices and any other control functions that may be required to operate the system (1000). Moreover, the example load lock system (1000) is configured such that operator access to the load lock gate (3020) and an operator interface to the system control module (1130) are each disposed on the same face of the system (1000) such that the load lock gate (3020) and control module interface (1130) are accessible from the same face.

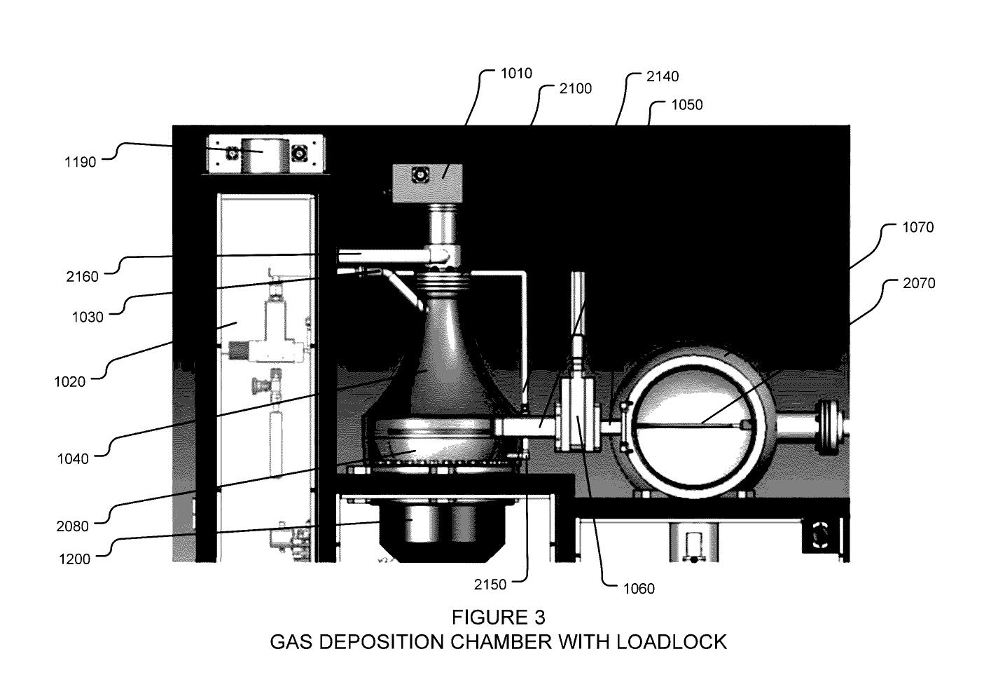

Referring to FIGS. 3-5 various partially transparent views of the mechanical interfaces between the gas deposition chamber (1040) and the and the spherical load lock chamber (1070) show the load port (1050) which is a rectangular port sized to accommodate passage of the substrate supported on a substrate holder (2070) there through. In addition, the gate valve (1060) is disposed in the load port (1050) between the load lock chamber and the deposition chamber to isolate the load lock chamber (1070) from the deposition chamber (1040) when the load lock chamber is at atmospheric pressure.

To move a substrate from the load lock chamber (1070) to the gas deposition chamber (1040), the substrate holder (2070) is initially positioned in the load lock chamber (1070). The substrate holder is sized to receive a substrate to be coated thereon and to pass the substrate through the load port (1050). To place the substrate to be coated onto the substrate holder (2070), the load port gate valve (1060) is closed to isolate the gas deposition chamber (1040) from the load lock chamber and the load lock chamber is purged to equalize its internal pressure with the local atmospheric pressure. Thereafter a user or automatic substrate manipulator, not shown, opens the load lock chamber gate (3020), inserts a substrate through the load port aperture (3010), and places it onto the substrate holder (2070). Typically, semiconductor wafers are handled using wafer tweezers to pass the wafer through the load port aperture for loading or unloading the wafer onto the substrate holder (2070).

In the present example, the substrate holder (2070) holds a thin circular disk shaped semiconductor wafer having a diameter of up to 200 mm. The wafer is substantially centered on the substrate holder by a circular flange (3035) shown in FIG. 4 or by another suitable centering device. Referring now to FIGS. 2-5, after inserting the substrate into the load lock chamber (1070) and closing the chamber gate (3020), the load lock chamber is pumped down to a vacuum pressure. The pump down may be performed by first using the roughing pump (1120) to pump to a first vacuum pressure, e.g. less than 1 ton, and then by using the turbo pump (1100) until the load lock chamber (1070) reaches a vacuum pressure that is substantially equal to the vacuum pressure of the gas deposition chamber (1040). Thereafter the gate valve (1090) is closed to isolate the load lock chamber from the turbo pump (1100) and the roughing pump (1120) and the load port gate valve (1060) is opened to provide a passageway between the load lock chamber and the gas deposition chamber.

Referring now to FIGS. 3-4, the gas deposition chamber (1040) includes a substrate support chuck (2080) which includes a circular substantially planar and horizontally disposed top surface for receiving the substrate support holder (2070) and a substrate to be coated centered thereon. Preferably, the substrate support chuck (2080) is heated by heating elements enclosed therein and described below. With the load port gate valve (1060) opened, the substrate holder is translated from the load lock chamber to the gas deposition chamber. Thereafter, the substrate holder is lowered slightly downward, along the vertical axis, such that a bottom surface of the circular substrate support holder (2070) makes contact with the circular top surface of the heated chuck (2080). The contact between the substrate holder and the support chuck (2080) allows thermal energy generated by the heaters inside the support chuck to be conducted through the circular substrate support holder (2070) to the substrate supported thereon.

Referring now to FIG. 4, the substrate holder (2070) includes an arc shaped load port shield (3060) disposed between the substrate support holder (2070) and the transport arm (1080). The transport arm includes a fixed outer sleeve (3050) and a movable inner rod (3045) attached to the arc shaped load port shield (3060). The inner rod (3045) is actuated by a transport mechanism, (1140) to transport the substrate holder (2070) through the load port (1050) and gate valve (1060) to center the substrate on the heated chuck (2080). The arc shaped load port shield (3060) is configured to mate with the arc-shaped gas deposition chamber wall surrounding the substrate load port aperture (3010) to cover load port aperture (3010) when the substrate and substrate holder are centered over the heated chuck (2080. As the load port shield (3060) approaches the gas deposition chamber wall surrounding the load port aperture (3010) the vacuum pressure inside the deposition chamber (1040) tends to draw the load port shield (3060) tightly against the gas deposition chamber wall surrounding the load port aperture (3010). Once drawn into contact, the load port shield (3060) prevents precursor and charged plasma gasses from escaping from the gas deposition chamber (1040) into the load port (1050) during coating cycles. In addition, a purge gas conduit (2140) is connected to the load port (1050) between the load port gate valve (1060) and the load port aperture (3010) and an inert purge gas is delivered into the load port (1050) during coating cycles, or continuously. A further purge gas conduit (2150) extends from the load port (1050) back into the gas deposition chamber (1040) vent the load port (1050) into the gas deposition chamber. The purge gas is delivered into the load port (1050) at a low mass flow rate but with enough pressure to develop a positive pressure gradient in the load port (1050) between the load port shield (3060) and the gas deposition chamber (1040) so that leakage through the load port shield (3060) will be from the load port (1050) to the gas deposition chamber (1040).

In the present example, the substrate holder (2070) comprises a solid thin disk formed from a unitary layer of metal, e.g. stainless steel or aluminum, with a high thermal conductivity for quick conduction of thermal energy from the heated chuck to the substrate. However, the highest substrate temperatures that will be required by the gas deposition processes also need to be considered when selecting the materials of substrate holder (2070) to ensure that deformation or melting of the substrate holder does not occur at high process temperatures. Similarly, the material of the arc shaped load port shield (3060) should be suitable for high temperature environments and may comprise stainless steel or aluminum. In a further aspect of the present invention, a bottom side of the substrate holder solid thin disk portion may be hollowed out in some areas, e.g. around the circumferential edge, to reduce material weight while still providing rapid thermal conduction from the heated chuck to the substrate. The substrate holder (2070) stays in the reaction chamber (1040) during processing and further serves to shield the horizontally disposed heated chuck substrate support surface to prevent material layers formed by the coating cycles being conducted in the gas deposition chamber from building up on the substrate support surface. The substrate holder (2070) also positions the substrate supported thereon in the coating position which is substantially centered over the horizontally disposed heated chuck substrate support surface and substantially coaxial with a substantially vertically disposed central axis of the gas deposition chamber and centered over heating elements disposed inside the heated chuck. When inserting or removing a substrate, the substrate holder (2070) is transported over the substrate support surface of the heated chuck without making contact with the heated chuck. However, once the substrate holder (2070) is in the coating position, it is lowered into contact with the heating chuck to remaining in contact with the heated chuck throughout the coating cycle. After coating, the substrate holder (2070) is then raised out of contact with the heated chuck for transport. In addition to reducing gas deposition chamber pump down time, the load lock configuration (1000) helps to prevent contaminants, such as water vapor, from getting into the gas deposition chamber (1040).

After the coating process is completed, the substrate is removed in reverse order of insertion by transporting the substrate support (2070) and substrate supported thereon back to the load lock chamber (1070), closing the load port gate valve (1060), purging the load lock chamber to atmosphere and removing the substrate through the lock port aperture (3010).

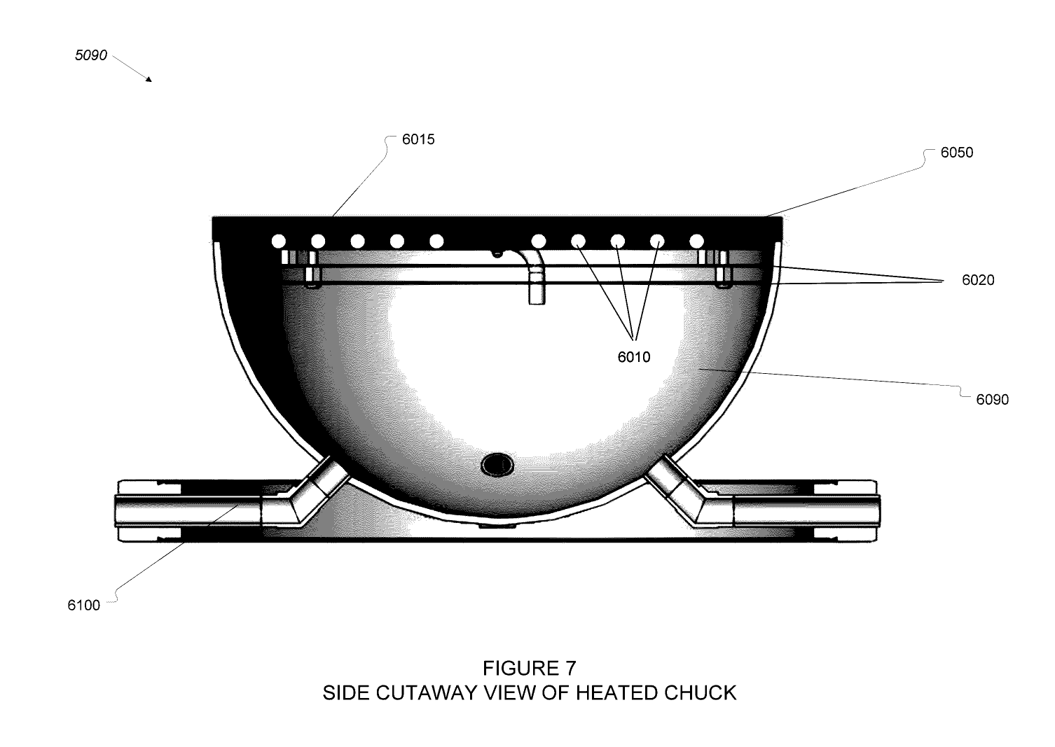

Referring now to FIGS. 6 and 7, an exemplary gas deposition chamber (5000) of the present invention is shown in side cut away view. The exemplary gas deposition chamber (5000) is shown with a manual substrate load port (5140) that includes a manually operable load port gate or door (5145). The gas deposition chamber (5000) and some exemplary implementations described below do not include a load lock chamber (1070) or load port gate valve (1060) as shown in FIG. 2 and the gas deposition chamber (5000) is configured for manual substrate loading and unloading, e.g. using manually held wafer tweezers or the like. Such systems are used for low volume coating runs, e.g. in a laboratory or preproduction testing facility, where an extended pump-down time for pumping the gas deposition chamber (5000) from atmospheric pressure to an operating vacuum pressure, e.g. less than 100 μTorr, for each new substrate is an acceptable tradeoff for reducing the cost and complexity of the system. Otherwise, the exemplary gas deposition chamber (5000) shown in FIGS. 6 and 7 and described below is usable in a wide range of system configurations without deviating from the present invention.

The gas deposition chamber (5000) extends along a substantially vertical central longitudinal axis (V) and comprises an external chamber wall (5105) formed to enclose a hollow gas deposition volume (5080) therein. The external chamber wall (5105) is open at top end thereof and forms a top circular aperture (5125) centered with respect to the axis (V). The chamber wall top end forms or is attached to a top or plasma source flange (5130) suitable for supporting a plasma source (5120) thereon and forming a vacuum seal with the plasma source (5120). In the present example, the top circular aperture (5125) is approximately 75 mm, (2.95 inches) in diameter.

The plasma source includes a plasma input port, (e.g. 2160 in FIGS. 3-4), that delivers plasma gases into the plasma source (5120) and directs the plasma gases into a plasma tube (5110). The exciter tube (5110) is surrounded by plasma exciter elements, not shown, suitable for exciting plasma gases passing through the exciter tube (5110) to a plasma state, and the exciter tube delivers the plasma gases through the tope circular aperture (5125) into hollow gas deposition volume (5080). Alternately, non-excited plasma gases and non-excited purge gases can be delivered into the hollow gas deposition volume (5080) through the exciter tube (5110). In addition, the reaction chamber (5000) is operable as a non-plasma system by removing the plasma source (5120) and gas sealing the top circular aperture (5125) by bolting a top plate to the plasma source flange (5130).

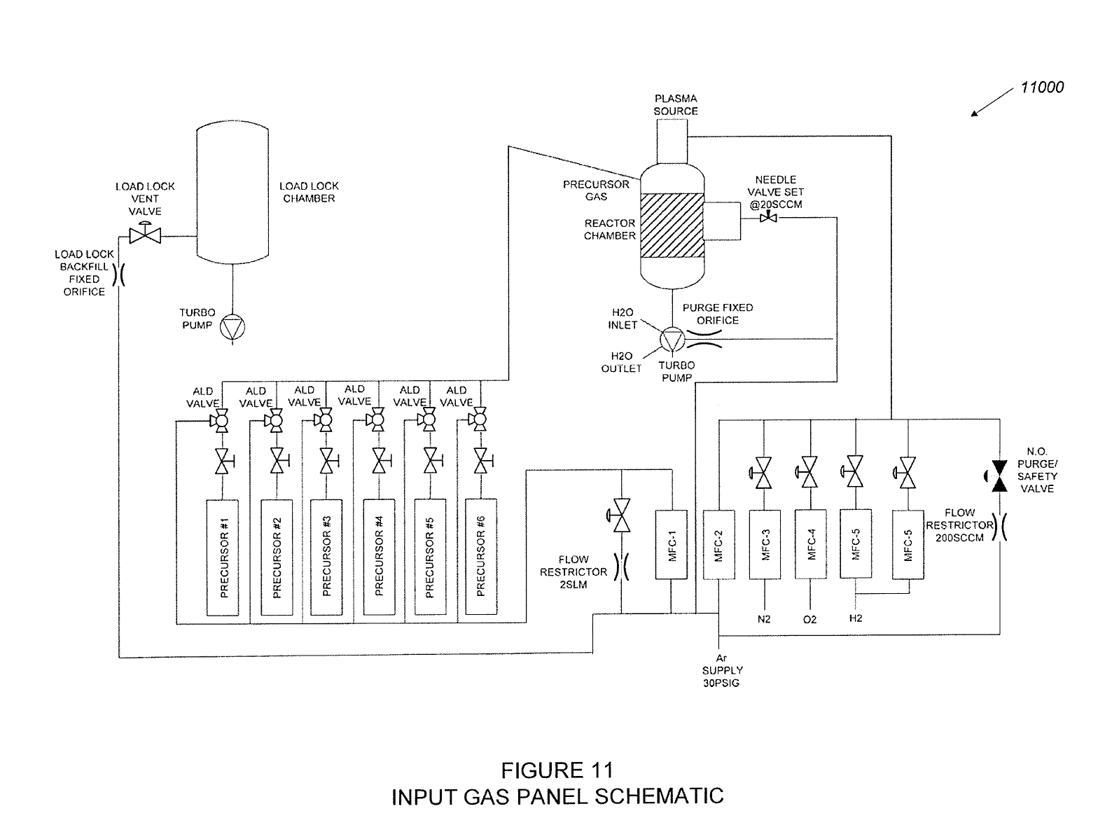

The plasma input port is in fluid communication with plasma gas supply containers housed in an input gas panel, shown schematically in FIG. 11, or plasma gas is otherwise delivered to the plasma source (5120). The input gas panel (11000) is configured to deliver any one of a number of various plasma gases to the plasma input port. The input gas panel includes control valves between each plasma gas source and the plasma input port and the control valves are configured to deliver precise mass flow rates of plasma gas and are controllable to open and close as needed to deliver the desired plasma gas. Similarly, the plasma source (5120) is controllable to excite the plasma gases to a plasma state or to pass unexcited plasma gases into the hollow gas deposition volume (5080) through the exciter tube (5110). The plasma gases, which may include H₂, O₂, N₂, and others, can be delivered with a continuous mass flow rate or delivered with a pulsed mass flow rate with gas pulses separated by periods of no plasma gas flow or reduced plasma gas flowing through the plasma input port. Similarly, the plasma source may be operated continuously to excite plasma gasses that flow through the exciter tube (5110) or the plasma source may be modulated to excite the plasma gas in pulses. Accordingly, either charged or uncharged plasma gases can be delivered through the exciter tube (5110). The uncharged plasma gas delivered through the exciter tube (5110) are usable to purge the hollow gas deposition volume (5080) to purge the exciter tube (5110) and to purge the plasma input port. In a preferred embodiment, a continuous volume of inert gas is delivered through the plasma input port and exciter tube (5110) to prevent deposition layers form forming on internal surfaces thereof.

A precursor gas port (5100) passes through the external chamber wall (5105) proximate to the top circular aperture (5215). In the present example, the precursor gas port (5100) is not directed vertically downward but instead the precursor gas port (5100) is oriented approximately at a 45-degree angle with respect to the (V) axis to direct precursor gas input flow exiting therefrom vertically downward but not along the vertical axis (V). The precursor port (5100) is in fluid communication with the input gas panel (11000) shown schematically in FIG. 11 or other gas source. The gas panel (11000) is configured to deliver any one of a number of precursor gases into the precursor gas port (5100) with precise mass flow rates modulated with precise pulse control to deliver gas volumes suitable for reacting with surfaces of a substrate to be coated. The gas panel (11000) is further configured to continuously deliver one or more inert gases such as nitrogen (N₂) through the precursor gas port (5100) as required to prevent deposition layers from forming on internal surfaces thereof. In addition, the inert gas delivered through the precursor port (5100) is usable to purge the hollow gas deposition volume (5080) such as to remove precursor or charged plasma gases therefrom. In a preferred embodiment, precursor gas delivery into the hollow gas deposition volume (5080) is delivered in precisely controlled pulses with a single precursor pulse having just enough or slightly more than enough gas volume to react with the surfaces being coated. The volume of each precursor gas pulse is controlled by providing a relatively constant gas mass flow rate modulated by a port valve that is opened for a pulse duration corresponding with a volume of precursor gas selected to be delivered into the hollow gas deposition volume (5080).

The external chamber wall (5105) is formed to surround a volume expanding top portion of the hollow the hollow gas deposition volume (5080). In the example embodiment shown in FIG. 6, the external chamber wall (5105) is formed with a constant radius (R). In other embodiments, the external chamber wall (5105) comprises a hyperboloid structure such as a single sheet hyperboloid of revolution with its transverse axis coplanar with the top aperture (5125). The volume expanding top portion extends from the top circular aperture (5125) to a cylindrical middle portion (5115). In the example embodiment of FIG. 6, the inside diameter of the top aperture is approximately 7.6 cm (3 inches) and the inside diameter at the bottom of the volume expanding top portion is approximately 30 cm, (12 inches) and the vertical height of the volume expanding top portion is approximately 1127.9 cm, (11 inches). In the example embodiment, the radius (R) is 33.93 cm (13.36 inches) and centered at a point 2.54 cm, (1.0 inches), below the top aperture and 37.74 cm, (14.86 inches) from the vertical axis (V). Preferably, the internal volume of the volume expanding top portion expands continuously from the top aperture to the middle portion, however a volume that expands in discrete increments along the vertical axis may be usable without deviating from the present invention.

The cylindrical middle portion (5115) of the external chamber wall is formed to surround a cylindrical middle volume centered with respect to the vertical axis (V). In the example embodiment of the chamber (5000), the cylindrical middle portion (5115) of the external chamber wall has a substantially constant internal diameter of approximately 300 mm, (11.8 inches) that is substantially coaxial with the axis (V). The cylindrical middle portion (5115) extends from the top portion to a circular exit aperture or exit port (5015) that is centered with respect to the vertical axis (V) and opposed to the top aperture (5125). A trap assembly (5020) interfaces with the exit port (5015) such that outflow from the hollow deposition volume (5080) exits through the trap assembly (5020). The trap assembly includes a conical portion (5030) that narrows in diameter to form a trap exit port (5060). The trap exit port (5060) is in fluid communication with the vacuum turbo pump (1100), which removes outflow from the hollow gas deposition volume (5080) and pumps the volume (5080) down to a desired vacuum pressure.

A heated chuck (5090) positioned inside the hollow gas deposition volume (5080) includes a substantially horizontally disposed substrate support surface (6015) for supporting a substrate thereon. A rectangular substrate load aperture (5135) extends through the middle portion of the external chamber wall (5105) opposed to the substrate support surface (6015). A substrate load port (5140) is attached to or integrally formed with the external chamber wall surrounding the substrate load aperture (5135) and provides a passageway for substrates to enter and exit the hollow chamber volume (5080).

The cylindrical middle portion (5115) and the trap assembly (5020) are attached together by opposing circular flanges (5155), with one circular flange being fixedly attached to or integrally formed with the cylindrical middle portion (5115) the other circular flange being fixedly attached to or integrally formed with the trap assembly (5020). The opposing circular flanges (5155) form a vacuum seal between the cylindrical middle portion (5115) and the trap assembly (5020) and are attach to a structural frame, not shown, to support the entire gas deposition chamber (5000) on the structural frame.

The trap assembly (5020) comprises a conventional ALD trap or filter such as the one disclosed in co-pending U.S. patent application Ser. No. 11/167,570, published as US Patent Publication No. 2006-0021573 by Monsma et al. entitled VAPOR DEPOSITION SYSTEMS AND METHODS, filed on Jun. 27, 2005, which is incorporated herein by reference in its entirety. The trap assembly (5020) includes a heated trap element formed with sufficient surface area to react with precursor and excited plasma gases passing through the trap assembly (5020) as they exit the hollow gas deposition volume (5080). In particular, the trap surface area may be heated to substantially the same temperature as the substrate being coated in order to cause the precursor or charged plasma gasses to react with the trap surface area and form the same material layers on the trap surface area as are being coated onto substrate surfaces by the coating process being carried out in the gas deposition chamber. Over time, material layers built up on the trap surface area may degrade trap performance so the trap element can be removed and replaced as required to maintain good trap performance.

Referring to FIGS. 6 and 10, the trap assembly (5020) includes a pressure gauge (5010, 9010) for determining a gas pressure inside the trap assembly. As shown in FIG. 10, and further described below, the trap assembly is fluidly connected with a high performance or turbo vacuum pump (1110) and a roughing vacuum pump (1120) which vents to a pump exhaust (9020). A stop or isolation valve (5025), gate valve (1190) or other computer controllable valve or valves may be disposed between the deposition chamber (5080) and the roughing vacuum pump (1120) as required to isolate the deposition chamber (5080) or direct gas flow as required. Accordingly, the vacuum system (10000), shown schematically in FIG. 10, is usable to pump the deposition chamber (5080) to a desired vacuum pressure, using the roughing pump (1120) and or the mag-lev turbo vacuum pump (1110). In addition, the turbo vacuum pump (1110) functions to remove outflow from the deposition chamber (5080) and vent the outflow to the roughing pump vent or pump exhaust (9020). The isolation valve (5025) or other suitable valves can be operated to selectively seal gas inside the hollow gas deposition volume (5080), e.g. to extend the exposure time that a precursor gas or charged plasma gas in the deposition volume is exposed to surfaces of a substrate being coated. In addition, any one of or all of the isolation valve (5025), or other valves, the turbo pump (1110) and the roughing pump (1120) may include a purge port that can be opened to purge the hollow gas deposition volume (5080) or other portions of the vacuum system (10000) to atmospheric pressure, e.g. when the manual gate (5145) needs to be opened to remove and or insert a substrate to be coated. In addition, the turbo pump (1110) and the roughing pump (1120) may be connected with a supply of inert gas usable to flush gases out of the vacuum system to the pump exhaust (9020).

The external chamber wall (5105) includes a top portion that extends from the top circular aperture (5125) to a top edge of the cylindrical middle portion (5115). In the example embodiment of FIG. 6, the mid portion of the chamber is formed with a substantially continuously increasing internal diameter that remains substantially coaxial with the axis (V) along its longitudinal length. More specifically, the top portion of the external chamber wall (5105) is formed to gradually increase the volume of the gas deposition volume (5080) from the top circular aperture (5125) to the interface with a top edge of the cylindrical middle portion (5115).

The heated chuck (5090) is disposed with its circular substrate support surface (6015) substantially coaxial with the vertical (V) axis and substantially coplanar with or slightly vertically below the interface between the volume expanding top portion and the top edge of the cylindrical middle portion (5115). Accordingly, a substrate being coated is substantially horizontally disposed on the substrate support surface (6015) with its circular center sustainably coaxial with the (V) axis and with the surface being coated exposed to a gas flow that has been expanded in volume and reduced in velocity by flow through the volume expanding top portion. In particular, the volume expanding top portion is formed to reduce the velocity of gas flow as the gas flows from input port (5100) and or exciter tube (5110) to the substrate support surface (6015) disposed in the cylindrical middle portion (5115).

In the exemplary embodiment shown in FIG. 6, the external chamber wall volume expanding top portion is formed with a constant radius (R) centered with respect to a radial axis (5165). Alternately, the external chamber wall top portion may comprises a continuous sidewall formed by a portion of a hyperboloid of revolution or circular hyperboloid centered with respect to the (V) axis. In other embodiments, the external chamber wall top portion may comprise a cone formed with straight sidewalls that extend along a line connecting the top circular aperture (5125) and a top edge of the cylindrical middle portion (5115). In any of these embodiments, the hollow deposition volume (5080) includes a top portion that substantially continuously expands in volume between a gas input region, e.g. proximate to the top circular aperture (5125), and a substrate support or coating region, e.g. proximate to a top edge of the cylindrical middle portion (5115). Moreover, according to an important aspect of the present invention, input gases are delivered into the gas deposition volume (5080) proximate to the top aperture (5125) and allowed to continuously expand in volume before reaching the substrate support surface (6015). The continuous chamber volume expansion is desirable because it gradually expands gas volume while simultaneously reducing gas flow velocity in order to reduce eddy current formation and promote laminar gas flow proximate to the substrate support surface (6015).

More generally, the shape of the hollow gas deposition volume (5080) as well as the position and shape of the heated chuck (5090) are configured to reduce aerodynamic drag or resistance to gas flow associated with a substrate supported on the substrate support surface (6015) and the heated chuck (5090). According to Bernoulli's equation, aerodynamic drag is proportional to the square of the gas flow velocity so any reduction in gas flow velocity proximate to the heated chuck (5090) serves to reduce the aerodynamic drag of the heated chuck (5090). According to the present invention, the velocity of gas flow exiting from the precursor port (5100) and or the exciter tube (5110) steadily decreases as the gas flow expands in volume along the gas deposition chamber top portion described above. Thus, the shape of the gas deposition volume (5080) and specifically the continuously increasing volume of the top portion of the external chamber wall (5105) from the top aperture (5125) to the cylindrical mid portion (5115) serve to decrease gas flow velocity and reduce aerodynamic drag caused by the heated chuck (5090). To further reduce aerodynamic drag or resistance to gas flow as it impinges on the heated chuck (5090) and flows around the heated chuck (5090) to the trap assembly (5020) the drag coefficient of the substrate support chuck (5090) support elements may also be reduced.

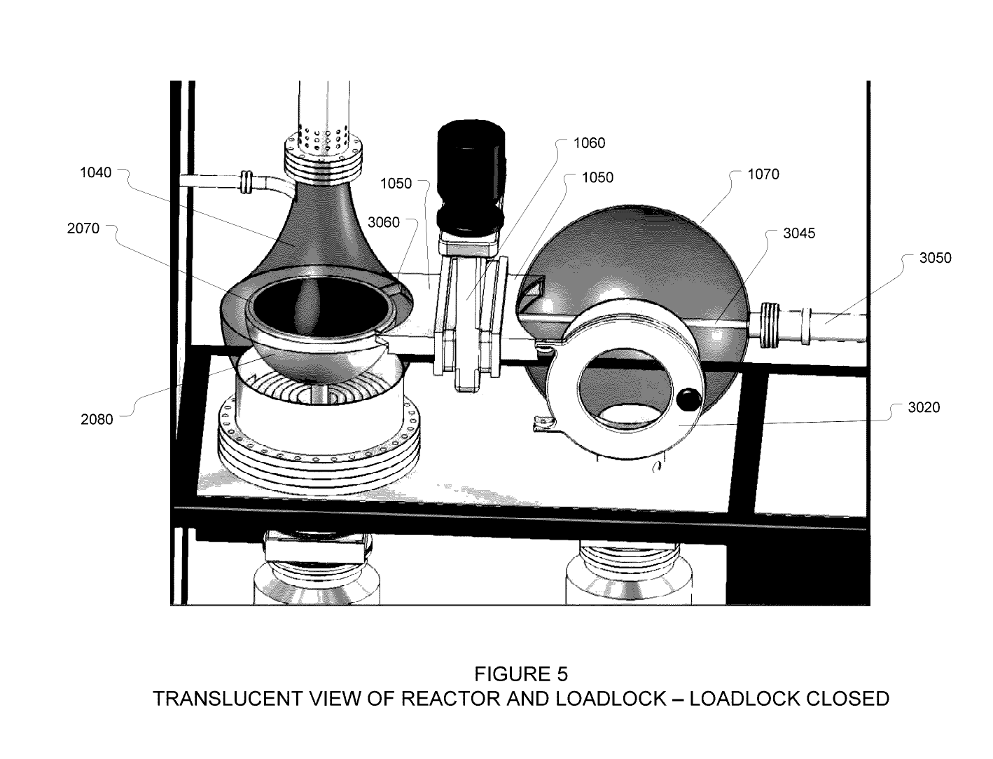

Referring to FIGS. 5 and 6, the heated chuck (5090) comprises a top circular plate (6050) comprising a metal having a high coefficient of thermal conductivity and suitable for high temperature environments such a stainless steel or a super alloy comprising iron, nickel and chromium know by the trade name INCONEL, a trademark of SPECIALTY METALS CORPORATION. The top circular plate (6050) forms a circular top surface (6015) oriented normal to and coaxial with the (V) axis for supporting up to a 200 mm diameter semiconductor substrate thereon for coating. The circular top (6015) has a diameter that is slightly larger than 200 mm (7.9 inches) and as best viewed in FIG. 7, a top circumferential edge of the circular top plate (6050) may be formed with a radius to reduce a drag coefficient of the heated chuck. A wafer substrate may be supported directly on the top circular plate (6050) e.g. when the wafer is manually installed, or the wafer substrate may be supported on the wafer holder, (e.g. 2070 in FIG. 5), which is held in contact with the circular top plate (6015) as described above.

The heated chuck (5090) further comprises a hemispherical outer shell (6090) that attaches to the circular top plate (6050) at a bottom circumferential edge thereof. The hemispherical outer shell (6090) is hollow and houses a plurality of electrical resistance heater coils (6010), or the like. The heater coils are positioned proximate to or formed integrally with the circular top plate (6050) or associated middle circular plates for heating the circular top plate (6050) and transferring thermal energy to a substrate supported on the substrate support surface (6015) or on a substrate holder (2070) in contact with the substrate support surface (6015). The electrical heaters may be opposed by reflective thermal baffles (6020) and or thermally insulating materials positioned to maintain the top circular plate (6050) at a desired operating temperature. The heated chuck (5090) may further comprise one or more temperature sensors positioned to detect local temperature and deliver a temperature signal to the system controller, (e.g. 1130 shown in FIG. 2). The system of the present invention is configured to operate with substrate temperatures that approximately range from 85-950° C. The hemispherical outer shell (6090) is shaped to provide a low aerodynamic drag coefficient. Other low drag coefficient outer shell shapes such as a paraboloid of revolution, e.g. a teardrop shaped outer shell, or a cone shaped outer shell are usable without deviating from the present invention.

The heated chuck is supported within the hollow gas deposition volume (5080) by three hollow tubes (6100) that each pass through and are held in place between the opposing flanges (5155). Each hollow tube (6100) is fixedly attached to the outer shell (6090) and the three hollow tubes are disposed approximately 60 degrees apart around the circumference of the outer shell (6090). The hollow tubes (6100) serve as conduits for passing electrical wires through the outer shell (6090) and may also serve as fluid conduits as may be required. The use of the three hollow tubes (6100) to support the heated chuck (5090) reduces aerodynamic drag in the region between the hemispherical outer shell (6090) and the internal diameter of the cylindrical middle portion (5115) by providing a substantially open conduit for the gas to pass through as is flows around the heated chuck (5090).

The improved gas deposition chamber (5000) includes external heating elements surrounding the external chamber wall (5105) and a thermal insulation layer surrounding the external heating elements. These are shown in phantom in FIG. 2. The external heating elements are usable to maintain the external chamber wall (5105) at a desired temperature that is different than and generally maintained at a lower temperature than the substrate temperature generated by the heated chuck. The gas deposition chamber (5000) may also include thermal sensors associated with the external chamber walls (5105) for sensing wall temperature and delivering a temperature signal to the system controller, (e.g. 1130 shown in FIG. 2). In addition, substantially all internal surfaces of the external chamber wall (5105) as well as all external surface of the heated chuck (5090) are roughened by sand blasting, shot blasting or bead blasting in a manner that improves adhesion of coatings formed thereon by ALD and PALD processes. The surface roughening helps to prevent cracking or chipping of gas deposition coating build up on internal surfaces of the gas deposition chamber over prolonged use. Accordingly, the built coating is prevented from breaking loose and contaminating of the hollow chamber the substrates installed within the hollow chamber, the trap assembly or the vacuum systems.

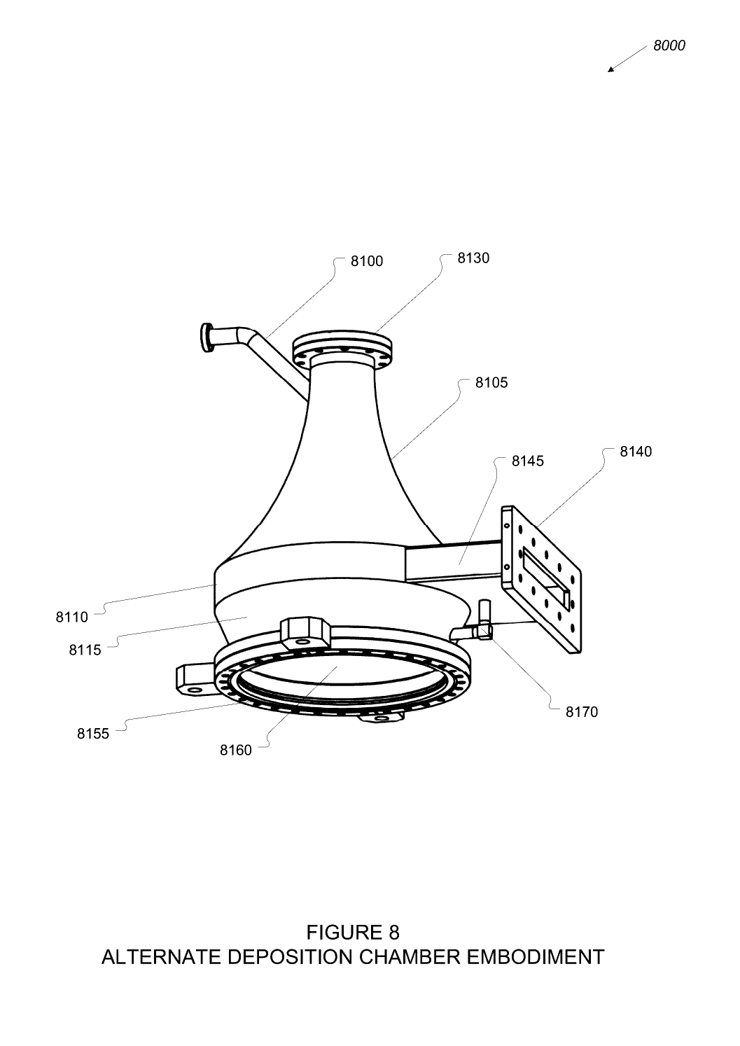

Referring now to FIG. 8, a second embodiment of a gas deposition chamber (8000) is shown in external isometric view. The gas deposition chamber (8000) comprises an external wall surrounding a hollow gas deposition chamber and the external wall includes a plasma source flange (8130) forming a circular aperture at a top end thereof. External walls of the hollow gas deposition chamber (8000) form a top portion (8105) extending between the plasma source flange (8130) and a cylindrical ring or middle portion (8110). The top portion is formed to continuously expand the volume of the enclosed gas deposition chamber between the plasma source flange (8130) and the middle cylindrical ring portion (8110). External walls of the hollow gas deposition chamber (8000) further form a lower portion (8115) that extends between the middle cylindrical ring portion (8110) and a trap flange (8155). The trap flange (8155) forms a bottom circular aperture (8160). A substrate support chuck is positioned inside the chamber (8000) through the bottom circular aperture (8160) and substrate support chuck is substantially similar to the chuck (5090) shown in FIG. 7. The substrate support chuck includes a circular substrate support surface that is horizontally disposed approximately centered with respect to the cylindrical ring portion (8110). A precursor port (8100) is attached to the top portion (8105) at a 45° angle from a vertical axis of the gas deposition chamber (8000).

A load port (8140) forms a substrate load port (8145) and a corresponding aperture, not shown, passing through the middle cylindrical ring portion (8110) for loading and unloading substrates into the gas deposition chamber (8000). The load port (8145) is substantially opposed to the substrate support surface provided by the substrate support chuck positioned inside into the gas deposition chamber (8000). The gas deposition lower portion (8115) is formed to reduce the internal chamber volume below the substrate support surface. More specifically, the lower portion (8115) is formed to more closely follow the contour of the substrate support chuck below the substrate support surface. The reduction of internal chamber volume below the substrate support surface serves to increase gas flow velocity below the substrate support surface and the increased gas velocity helps to reduce the time required for a given gas volume to flow through the gas deposition chamber (8000). Thus the shape of the lower portion (8115), which is formed to reduce the internal chamber volume below the substrate support surface, reduces gas deposition cycle times.

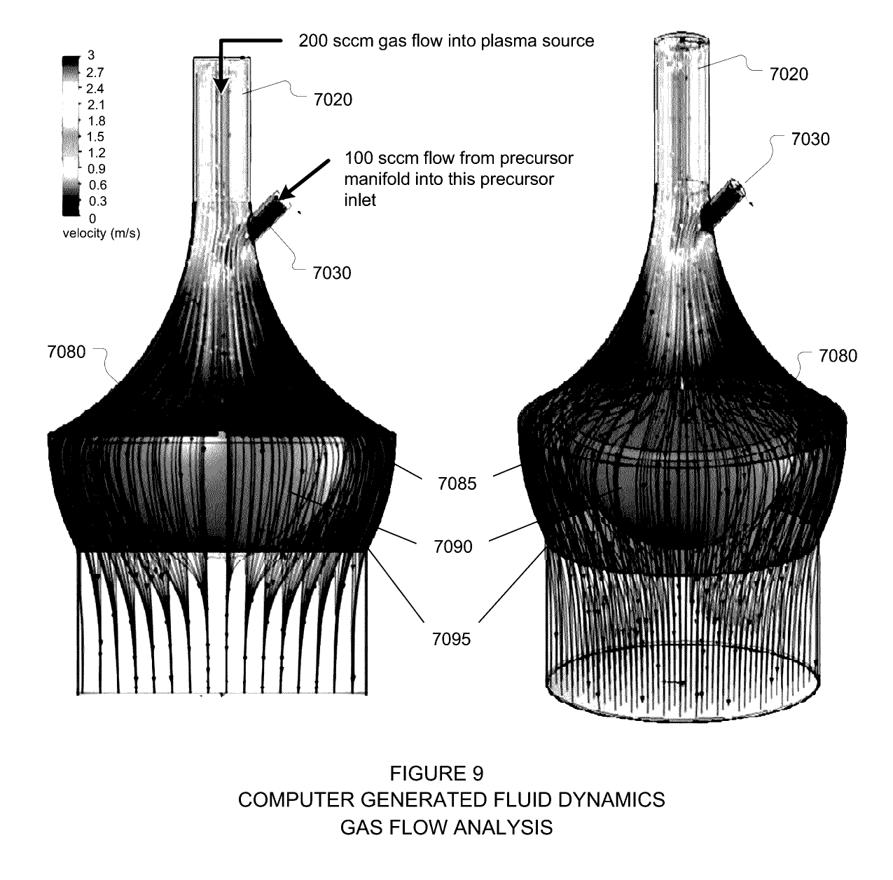

FIG. 9 depicts a graphic representation of gas flow dynamics associated with one embodiment of a gas deposition chamber according to the present invention. The graphical representation of gas flow dynamics is based on a computer model of a gas deposition chamber that includes a narrow top aperture (7020), a volume expanding hyperboloid shaped top portion (7080), and a volume reducing paraboloid shaped lower portion (7085). The model includes a substrate support chuck (7090) that includes a circular substrate support surface and a substantially hemispherical base portion. The chuck (7090) is positioned inside the gas deposition chamber with the circular substrate support surface horizontally disposed at a transition between the top volume-expanding portion (7080) and the lower volume-reducing portion (7085). The model includes a first gas flow directed downward along a vertical axis from the top aperture (7020) and a second gas flow directed along an axis rotated 45 degrees with respect to the vertical axis through an input port (7030). In particular, the graphic representation of gas flow dynamics shown in FIG. 9 most closely models the gas deposition chamber (8000) shown in FIG. 8.

The gas flow model uses a constant input volume of 100 Standard Cubic Centimeters per Minute (SCCM) through the input port (7030) and a constant input volume of 200 SCCM through the top aperture (7020). The resulting graphical plots shows a flow velocity entering the deposition chamber through the input port (7030) of approximately 3.0 Meters per Second (m/s) and a flow velocity entering the deposition chamber through the through the top aperture (7020) in the approximate range of 1.2 to 3.0 (m/s). The graphical plots further shows a gas flow impinging on the substrate support surface that has a substantially constant velocity of less than 0.3 m/s over the entire circular surface. The graphical plots further shows gas flow direction vectors indicated by arrowheads. The arrowheads show that gas impinging onto the substrate support surface substantially flows radially outward toward the circular peripheral edge of the substrate support surface and over the circular peripheral edge toward the bottom circular aperture (7095).

Moreover, the graphical plots shown in FIG. 9 demonstrate that gas flow velocity is highest in the input port (7030), next highest in the top aperture (7020), and that gas flow velocity is reduced to a substantially uniform flow velocity about half way between the input port (7030) and the substrate support surface. The graphical plots further confirm that gas flow over the substrate and around the substrate support chuck is substantially laminar because adjacent flow vectors, represented by the arrowheads, are substantially parallel. As a result of the substantially laminar flow, the deposition gases are more uniformly distributed over the substrate support surface and the time required to pass a given volume gas through the deposition chamber is reduced such that the duration of each coating cycle is also reduced. An additional benefit of the gas deposition chamber configurations of the present invention is that they eliminate virtual vacuum voids such as rectangular corners, recesses or other pockets that can trap gas and hinder evacuation of the chamber. The lack of such vacuum voids in the gas deposition chamber embodiments described herein help to reduce the range of vacuum pressure fluctuations per coating cycle and this also reduce gas deposition cycle times.

FIG. 10 is a schematic representation of an exemplary vacuum system (10000) usable with the present invention and specifically relates to the system (1000) shown in FIG. 2. The vacuum system (10000) interfaces with electrical control systems to perform automated coating cycles, to interlock valves and or pumps from operating if the action would result in an unsafe condition or cause damage to the equipment and to perform various purges, pump down cycles, and other gas flow characteristics as may be preprogrammed or manually selected by a user. As shown in FIG. 10, the load lock chamber (1070) includes a wafer load port (3010) and linear wafer transport system (1080/1140) associated therewith. A first load lock gate valve or isolation valve (1190) is usable to isolate the load lock chamber (1070) from the first turbo vacuum pump (1100) and the roughing pump (1120). A vacuum gage (9010) is disposed between the load lock chamber (1070) and the first turbo vacuum pump (1100) for detecting and reporting gas pressure in the load lock chamber. In addition, a first stop valve (1150) is usable to isolate the first turbo vacuum pump (1100) from the roughing vacuum pump (1120). The load lock chamber (1070) further interfaces with a chamber gate valve (1060) disposed between the load lock chamber (1070) and the gas deposition or reaction chamber (1040). A soft start valve (9050) is provided in vacuum line between the roughing pump (1120) and the load lock chamber (1070) to directly pump the load lock chamber down with the roughing pump (1120).

On the reaction chamber side, a second turbo vacuum pump (1110) is usable to pump down the reaction chamber (1040). A second vacuum gage (5010) is disposed between the second turbo vacuum pump (1110) and the deposition chamber (1040) for detecting and reporting gas pressure in the deposition chamber. A second isolation valve (5025) is disposed between the roughing pump (1120) and the second turbo vacuum pump (1110) to isolate the deposition chamber (1040) from the roughing pump. The roughing pump (1120) includes an exhaust port (9020) that is vented to a safe venting area and outflow from the reaction chamber (1040) is preferably vented to the exhaust port (9020). In addition, the deposition chamber includes a top aperture (2010) for attaching a plasma source to the deposition chamber (1040) and the plasma source may deliver charged or uncharged process or inert gases into the deposition chamber. In other embodiments, the top aperture is sealed if the system (10000) is configured without a plasma source. The vacuum system (10000) may also include one or more ports, e.g. (9030) in the load lock chamber, (9040) in the second turbo pump (1110), (9050) in the roughing pump (1120) and (2140) in the substrate load port, to deliver a purge gas into various portions of the vacuum system to increase gas pressure or to purge unwanted gases from the region being purged.

Referring now to FIG. 11 an exemplary gas input system usable with the present invention is shown schematically. The input gas system (11000) interfaces with electrical control systems to perform automated deposition coating cycles, to interlock valves and or pumps from operating if the action would result in an unsafe condition or cause damage to the equipment and to deliver process gasses into the deposition chamber. In addition, the input gas system (11000) may be used in cooperation with the vacuum system (10000) to perform various purges, pump down cycles, and other gas flow dynamics as may be preprogrammed or manually selected by a user. In particular, the input gas system (11000) is configured to operate in any of a number of different gas deposition modes including a conventional or thermal ALD mode, a plasma assisted PALD mode, a chemical vapor deposition, (CVD) mode and other modes as may be preprogrammed or manually set up by a user. In addition, due to the wide range of substrate temperatures allowed by the present invention, the exemplary gas deposition chambers described herein may be usable to grow carbon nanotubes from a starter material loaded onto the substrate support surface and thereafter to coat the carbon nanotubes in situ by any one of the gas deposition processes described above.

Generally the vacuum system (10000) and the gas input system s (11000) shown in FIGS. 10 and 11 are controlled by the system controller (1130) described above. In addition, the input gas system (11000) includes heating elements that heat process gasses such as precursor and or plasma gases to desired input gas temperatures. The system controller (1130) includes a user interface suitable for selecting process recipes, inputting new commands and or altering an ongoing process. Process recipe parameters may include the type of input gases that will be injected into the gas deposition chamber, the input gas temperatures, input gas mass flow rates or total gas volume, plasma source parameters such as plasma gas type, plasma gas mass flow rates or total volume, plasma source pulse duration, deposition chamber pressures, purge gas type, number of deposition cycles to perform and any other gas input and vacuum system control parameters that may be required. In addition, the recipe parameters may include the substrate material, the substrate temperature, the chamber external wall temperature, exposure times and other parameters as may be required. In some instances a recipe may be preprogrammed and selected by one or a small number of process selection choices such as by selecting a substrate material or type, a coating material or type and a desired coating thickness. In other instances, a user may design or otherwise vary process recipes according to the needs of the user. However, the system controller (1130) may also include recipe control software that warns a user when a selected recipe is not recommended, e.g. if the selected recipe cannot be preformed by the current system configuration, if the selected recipe is not compatible with the substrate material or gas selections, or if the selected recipe may result in an unsafe condition. Otherwise, the recipe warning system may also present warnings that the selected recipe may result in very long cycle time or excessive precursor use or other conditions that may be helpful to the user.

More generally, with respect to the reaction or deposition chambers of the present invention, the gas input system (11000) is configured to deliver a continuous flow of inert or purge gas through each of the process gas input lines associated with the deposition chamber. The continuous flow of inert gas serves as a carrier gas suitable for carrying process gases into the gas deposition chamber and serves to prevent process gases from entering the process gas input lines from the gas deposition chamber and possibly mixing in the gas input lines to coat internal surfaces of the gas input lines with solid layers. In addition, for each process gas input line or port, the gas input system (11000) is configured to select one process gas from a plurality of process gas supply containers in fluidic communication with the gas input line and to deliver the selected process gas into the input line. Process gases may be delivered in a continuous flow stream or in pulses controlled by opening and closing a gas pulse valve disposed between the input line and a process gas supply. In addition, the gas input system may deliver a continuous or a non-continuous flow of inert gases to various other lines and ports used to flush out or change the gas pressure in other regions of the gas deposition system as may be required.

The components of the exemplary gas deposition systems described above can be associated in various orientations and combinations so as to produce a variety of configurations, each with characteristics useful to a particular purpose. Each configuration may include four external side faces such as opposing front and back faces and opposing left and right side faces. In addition, each system includes at least one load port for loading and unloading substrates for coating and at least one user interface area that is usable to enter commands for controlling the gas deposition system. In the systems described below, whichever face includes the load port or ports is considered the system front face. The example gas deposition systems may comprise stand-alone gas deposition chambers as may be used in a laboratory or for low volume preproduction testing or the example gas deposition systems may be configured to cooperate with other systems such as a load lock port, substrate loading and unloading system or other automated device. The example gas deposition systems described below may be configured for zero “zero footprint” use wherein the entire gas deposition system is located outside a clean room or other process area where space is limited and but configured to be loaded, unloaded and operated from inside the clean room.

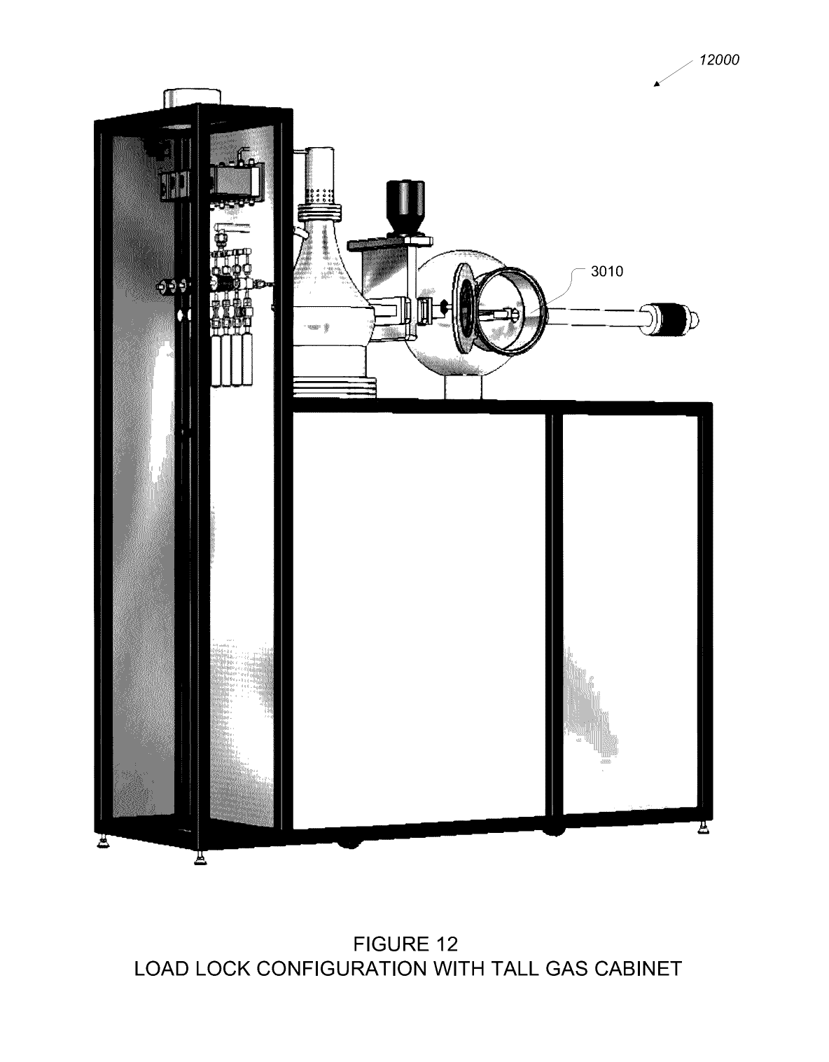

Referring now to FIG. 12 a gas deposition system (12000) comprises a load lock system configuration with a tall gas cabinet (12000). This configuration is suitable for standalone use, or for “zero footprint” configurations. A load lock chamber port (3010) is provided on a front face and may be positioned with access to the port (3010) provided through a clean room wall with the entire system (12000) located is outside of the clean room. In addition, the tall gas cabinet reduces the system overall system footprint and provides user access from a left side of the system.

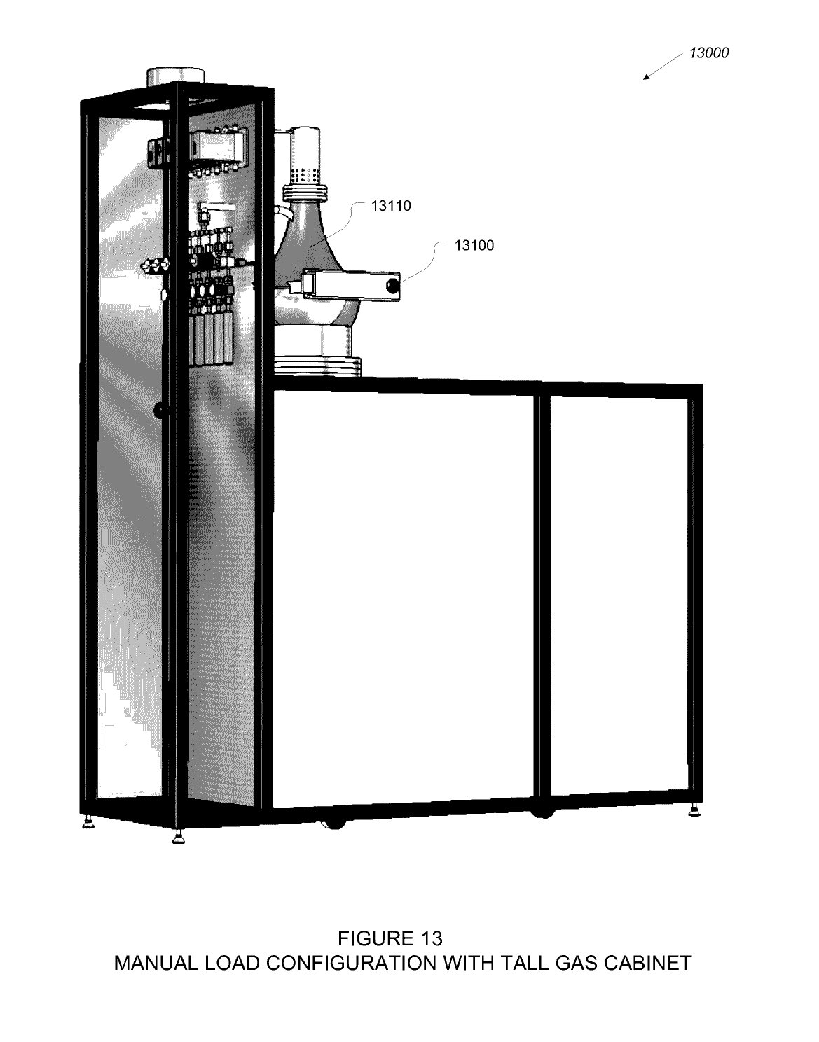

Referring to FIG. 13, a gas deposition system (13000) is configured for a manual loading through as front face. The system (13000) is suitable for both standalone and “zero footprint” installations. A manual load port (13100) and associated door are directly mounted to a deposition chamber (13110) for loading a substrate directly into the deposition chamber e.g. using wafer tweezers or other suitable handling device. The load port (13100) may be made accessible from inside a clean room to allow loading from the clean room. This configuration also comprises a tall gas cabinet to reduce its overall footprint.

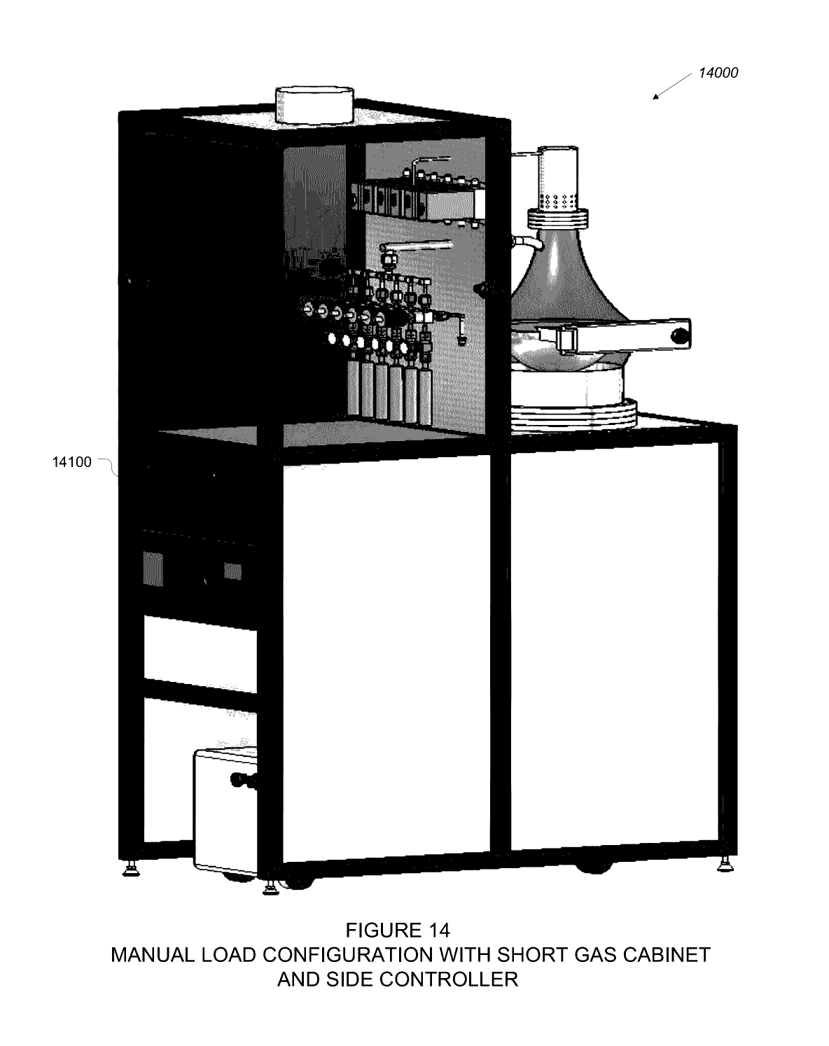

Referring to FIG. 14 a manual front load system configuration (14000) that includes a combined short gas cabinet and left face-mounted electronic controller and associated user interface (14100). This configuration includes a manual load port and associated door attached to a deposition chamber. The manual load port may extend through or be made accessible through a clean room wall to allow loading and unloading from the clean room.

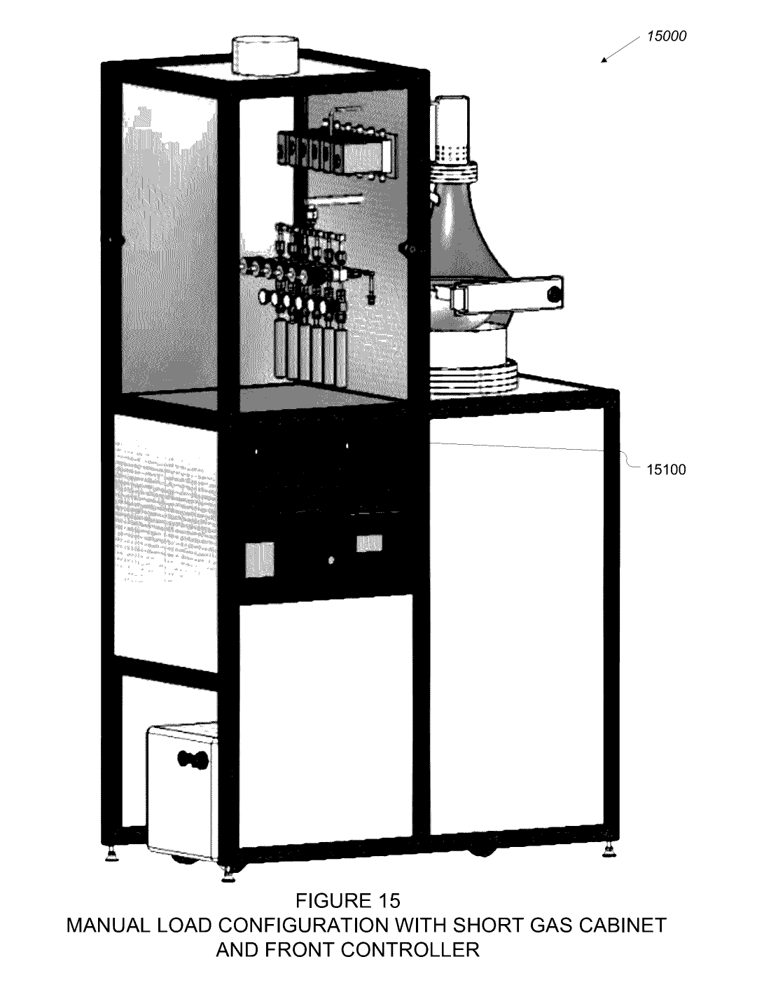

Referring to FIG. 15, a manual front load system configuration (15000) includes a short gas cabinet and front face mounted electronic controller and associated user interface (15100). The system (15000) is most suitable for a stand-alone device wherein a user may access the load port and controls from the front face. However, in “zero footprint” installations the manual load port and controller may be made accessible from inside a clean room with access through a clean room wall.

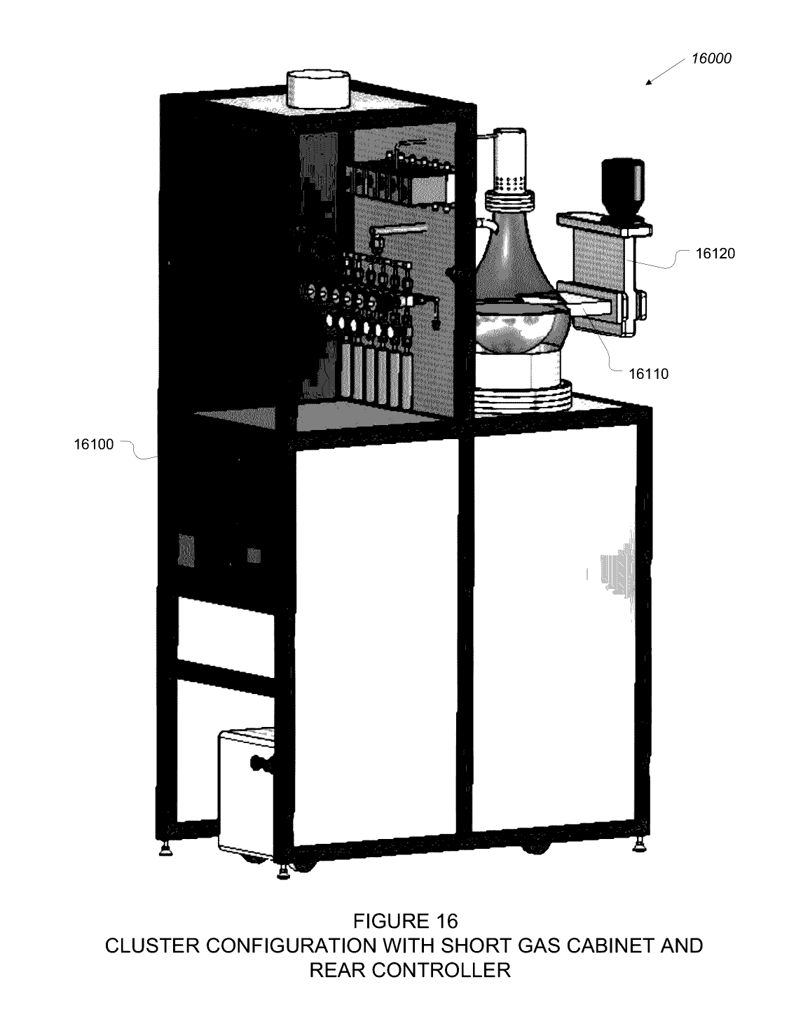

FIG. 16 depicts a gas deposition system (16000) that includes a front face configured to interface with a cluster module or the like and with the electronic controller and associated user interface (16100) located accessible from a back face of the system. The system (16000) includes a short gas cabinet, and electronic controller and user interface (16100) disposed under the gas cabinet. A load port (16110) is attached to a gas deposition chamber and faces the front face. Since no access is required to the sides of the system to operate or load it, this configuration is suitable for cluster configurations, where a plurality of systems are installed adjacent to each other or encircling a central load lock chamber. The load lock port (16110) with a gate valve (16120) is useful when interfacing with automated substrate handling systems such as might be used in a production facility.

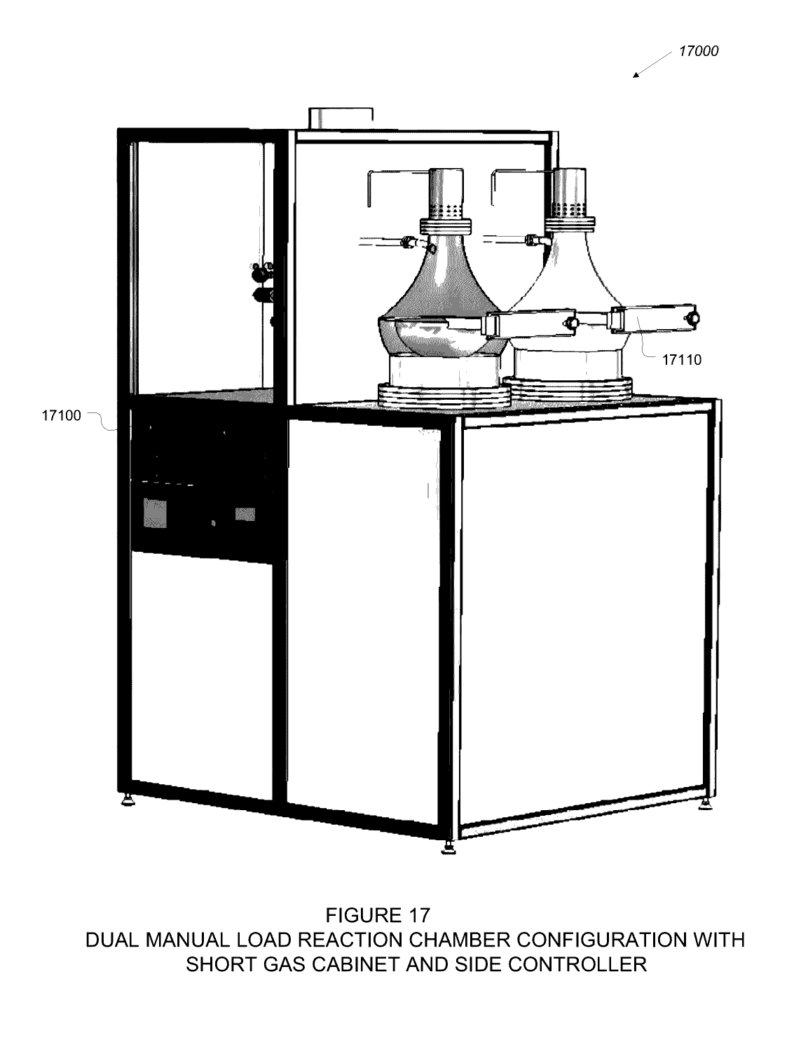

In a further step toward space saving and component sharing, FIG. 17 depicts a dual gas deposition chamber configuration (17000) with a single frame supporting two gas deposition chambers each included a two front facing manual load ports and load port gates or doors (17110) attached thereto. The system (17000) includes a short gas cabinet accessible form a back face and a left side accessible electronic controller and associated user interface device (17100). In this configuration, two manual direct entry load port gates (17110) may be arranged for access from inside a clean room, with the controls and user interface (17100) outside the clean room. It is noted that each of the gas deposition chambers of the system (17000) includes a complete and independent gas panel, vacuum system and electrical control system so that each gas deposition chamber can be operated simultaneously and independently of the other. Such configurations can also be operated as stand-alone systems when desired.

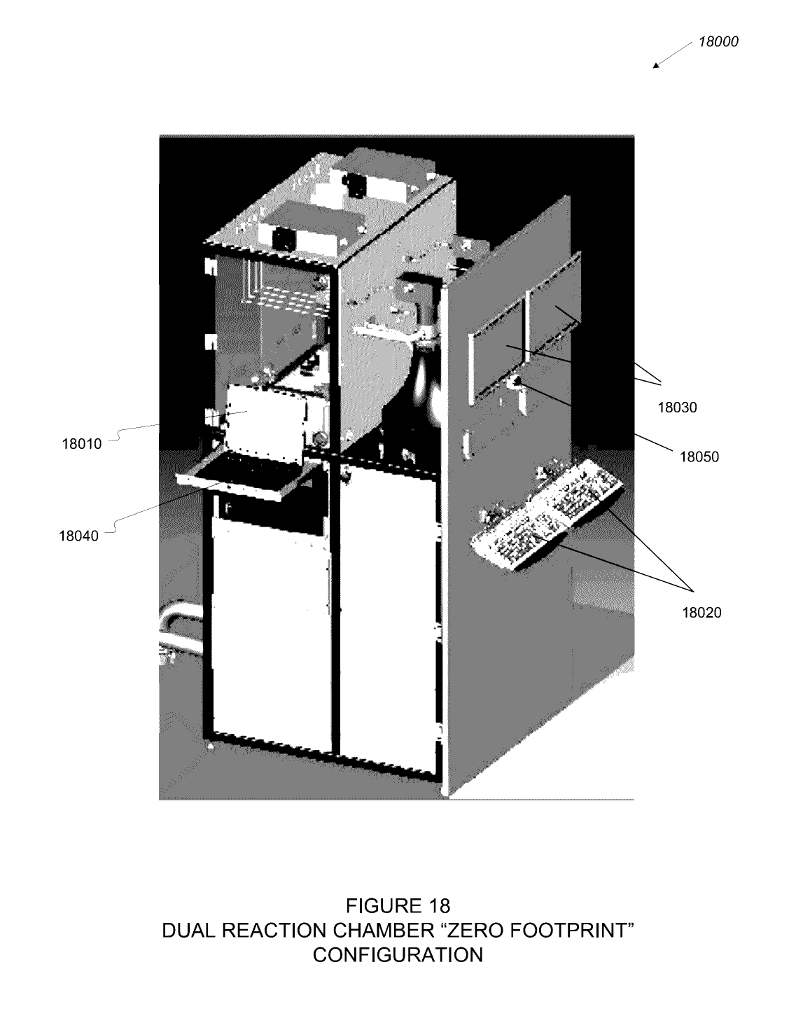

FIG. 18 depicts an isometric view of a dual-chamber configuration (18000) being used in a zero footprint installation, with two separate user interfaces provided on a front wall of the system (18000) or mounted inside the clean room, as shown. Each user interface may include operator input controls (18020), such as a keypad or the like, and a display device (18030). Each user interface is associated with a separate gas deposition chamber. Each user interface is located inside the clean room or is accessible from inside the clean room, and is interconnected with the system electronic controller either by a direct hard wire or wireless connection, or over a wire or wireless network interface. As a safety feature, a single emergency shutdown control (18050) may be disposed inside or accessible from inside the clean room to permit a user to shut off power to both gas deposition chambers and close all gas supply valves in emergency situations where a more normal, and lengthy, shutdown is not possible, or safe.

The system (18000) may also include one or more service interface devices interconnected with the system electronic controller. In particular, each service interface device is preferably outside the clean room and may be disposed on a non-front face of a zero footprint installation, as shown. Each service interface device is usable by a service operator, shift supervisor or the like to activate system maintenance and other non-operational procedures such as for shutting down the system, including an emergency shut down, reconfiguring the system, updating system control programs, adding new coating recipes, performing diagnostic tests, and any other non-routine control functions as may be required. In particular, each service interface device may include operator input controls (18040), such as a keypad, or the like, and a display device (18010). The service interface device or devices may be located in a locked drawer outside the clean room and may be configured to take precedence over the user interface controls located inside the clean room such that the user interface devices may be non-responsive when the service interface device are being accessed or when service tasks are being performed. This increases safety for the service personnel by preventing a user from initiating operations while the system is being worked on. The system (18000) includes two complete and independent gas deposition systems supported on a single frame. Each system can be operated simultaneously and independently of the other and the single frame reduces the cost and floor space footprint when compared with two separate systems.

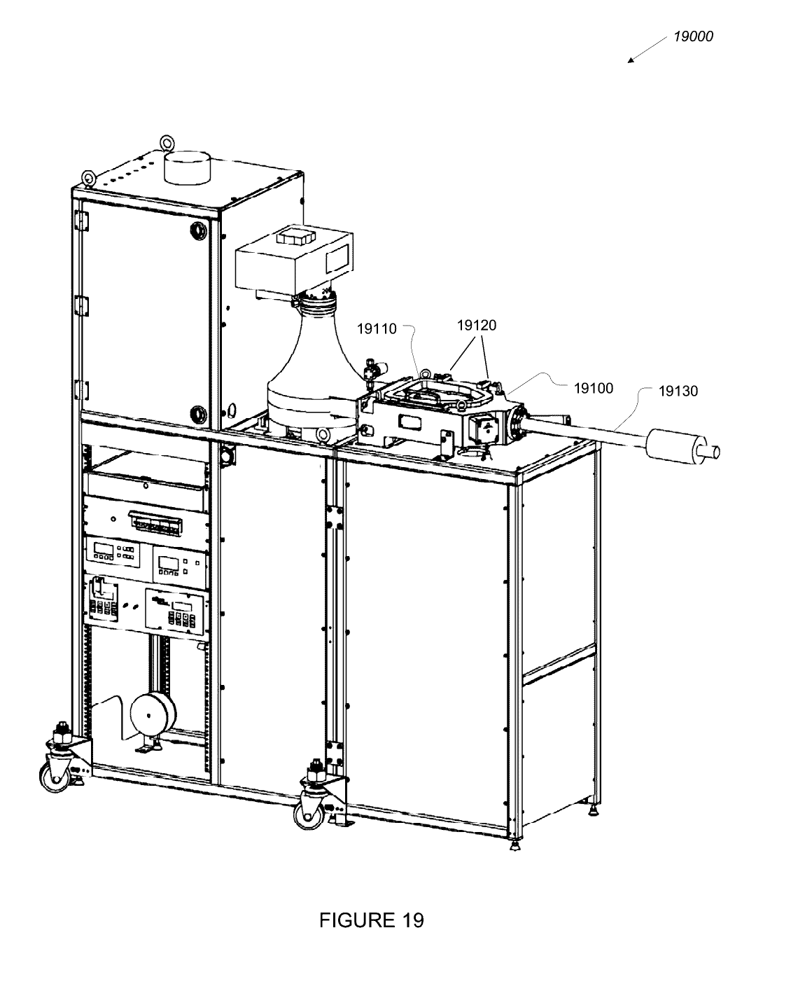

Referring now to FIG. 19, a further system of the present invention (19000) includes a top loading rectangular load lock chamber (19100). The load lock chamber (19100) includes a top access load port gate or door (19110) configured to pivot upward on back hinges (19120) to provide access to a substrate handler disposed inside the load lock chamber (19100). The load lock chamber (19100) includes a transport arm (19130) which by be operated automatically or manually to transport a substrate from the load lock chamber to a gas deposition chamber.

Referring now to FIG. 16, the front face of the system (16000) and particularly the load port conduit (16110) may be interfaced with a load lock chamber, a clean room, a robotic or automated substrate loading and unloading device or any other device suitable for loading and unloading substrates into and out of the gas deposition chamber (16130) through the load port conduit (16110). In addition, the electronic controller (16100) may also include wire or wireless communication channels suitable for communicating with an automated loading and unloading device, independently of a user, and may be configured to exchange load and unload commands with an automated loading and unloading device.

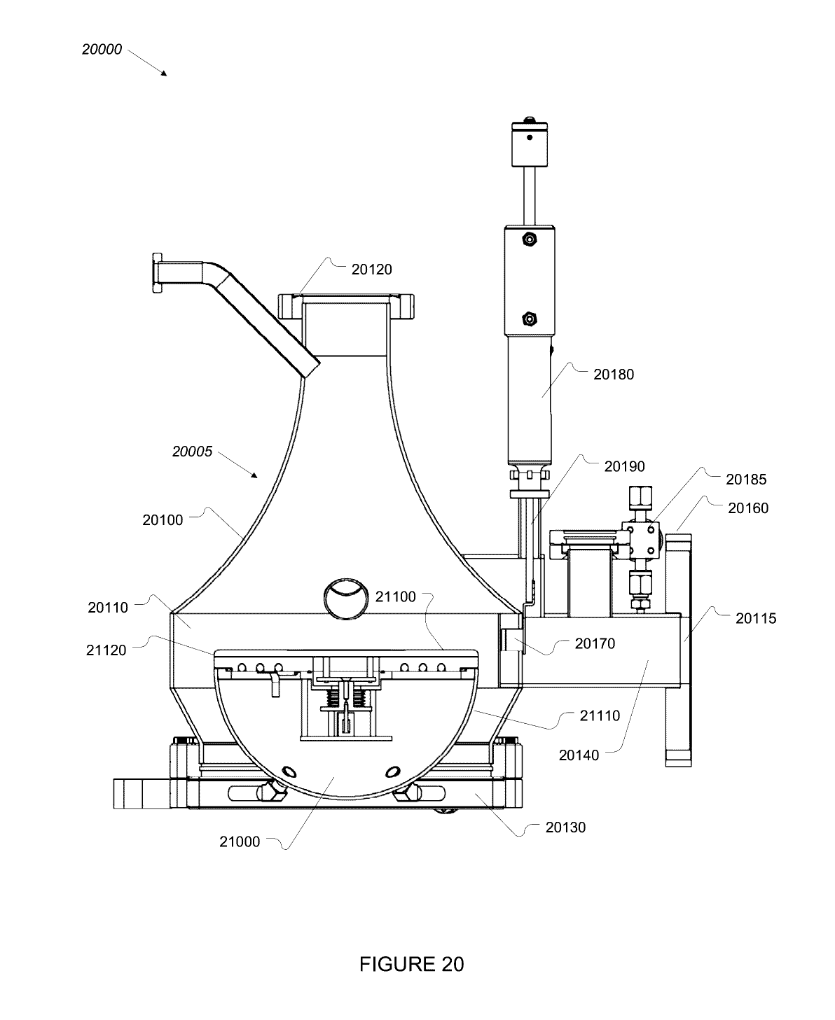

Referring now to FIGS. 20-22, an exemplary embodiment of a gas deposition chamber (20000) and a corresponding substrate support chuck (21000), each modified for automatic substrate handling are shown in a transparent view in order to show the position of the substrate support chuck (21000) inside the gas deposition chamber. Referring to FIG. 20, the gas deposition chamber (20000) includes an outer wall (20100), surrounding a hollow deposition chamber (20110) with a plasma source flange (20120) forming a top circular aperture and a trap assembly flange (20130) forming a bottom circular aperture. The substrate support chuck (21000) includes a to circular substrate support surface (21100) for receiving substrates being coated thereon. The substrate support chuck (21000) is formed with a hemispherical bottom portion (21110) and with a radius (21120) formed on a circumferential edge of the substrate support surface to reduce aerodynamic drag.

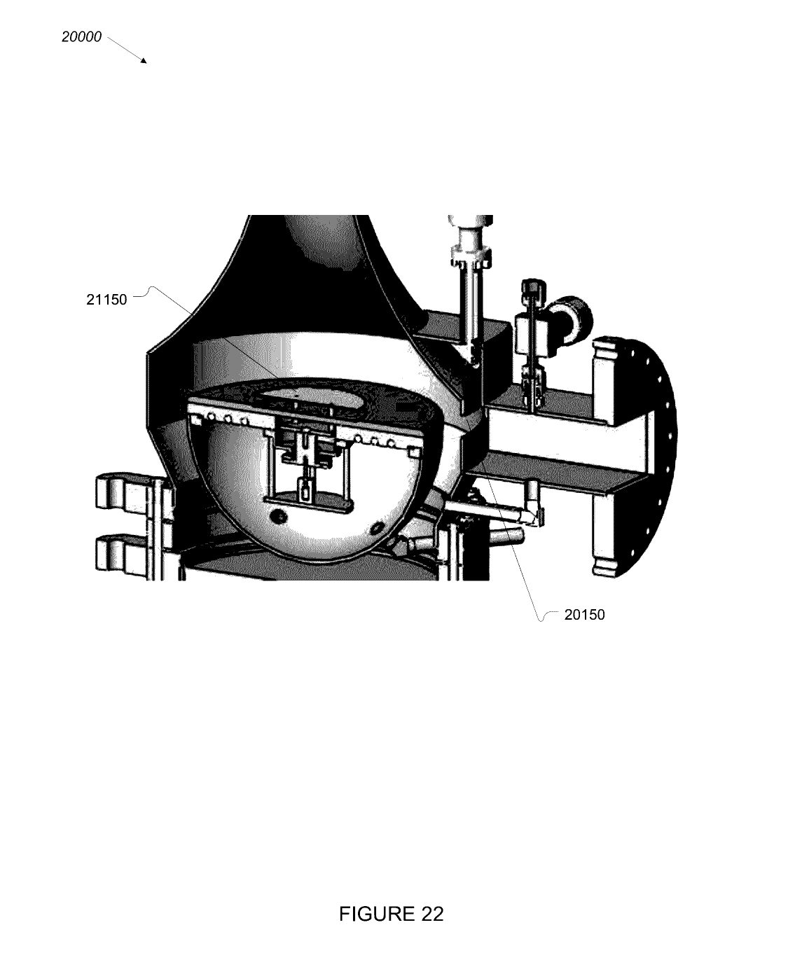

A load port (20140) comprises a rectangular conduit formed integral with or otherwise fastened to the chamber outside wall (20100). The load port (20140) includes a rectangular load port aperture (20150), shown in FIG. 22, passing through the chamber outside wall (20100). A vertical center of the load port aperture (20150) approximately aligns with the substrate support surface (21100). The load port (20140) further includes an end flange (20160) suitable for interfacing with a load lock chamber or other vacuum chamber and or a clean room associated with an automated substrate loader. The end flange (20160) is formed with a rectangular input aperture (20115) passing there through such that substrates can be passed through the load port to the hollow deposition chamber (20110). The load port (20140) further includes a movable load port aperture cover (20170). The cover (20170) is attached to shuttle mechanism (20180) by a link (20190) and the cover, shuttle mechanism and link are configured to move the cover (20170) between a down position, that causes the cover to overlap the load port aperture (20150) during gas deposition cycles, and an up position that causes the cover (20170) to uncover the load port aperture (20170) during substrate loading and unloading.

In the present embodiment, the shuttle mechanism (20180) comprises a pneumatic piston that advances the link and attached cover between the up and down positions in response to air pressure changes. Other actuator mechanisms are also usable. The cover (20170) may comprise a sheet metal element formed with a semicircular arc that substantially matches the outer radius of the outer wall (20100) and sized to completely overlap the load port aperture (20150). In the down or closed position, the cover merely contacts the outer radius of the outer wall (20100) without forming a gas seal. However, as the hollow deposition chamber (20110) is pumped down to a vacuum pressure suitable for deposition coating, the cover (20170) may be drawn tightly to the outer wall to at least partially seal the load port aperture during deposition cycles. This help to contain precursor and charged plasma gases within the hollow deposition chamber (20110) in order to avoid solid material layer formation inside the load port (20140).

To further prevent deposition gasses from entering the load port (21040), a purge line and valve (20185) are connected to an inert gas supply and disposed to deliver a continuous flow of inter gas into the load port rectangular conduit between the flange (20160) and the load port aperture (20150). The inert gas flow generates a positive gas pressure gradient between the load port rectangular conduit and the hollow deposition chamber (20110). As a result, any gas leaks around the cover (20170) will tend to leak from the high-pressure side, inside the load port, to the low-pressure side, inside the hollow deposition chamber (20110) thereby further helping to contain deposition gases inside the hollow deposition chamber. In addition, the positive gas pressure gradient in the load port helps to prevent contaminates from entering the load port (20140) through the input aperture (20115). In order to avoid excessive gas pressure build up in the load port (21040), a vent tube (8170), shown in FIG. 8, may be included to provide a gas flow conduit that extends from the load port rectangular conduit into the hollow deposition chamber (20110). Alternately, a relief valve or other venting arrangement may be used to prevent excessive pressure build up in the load port.

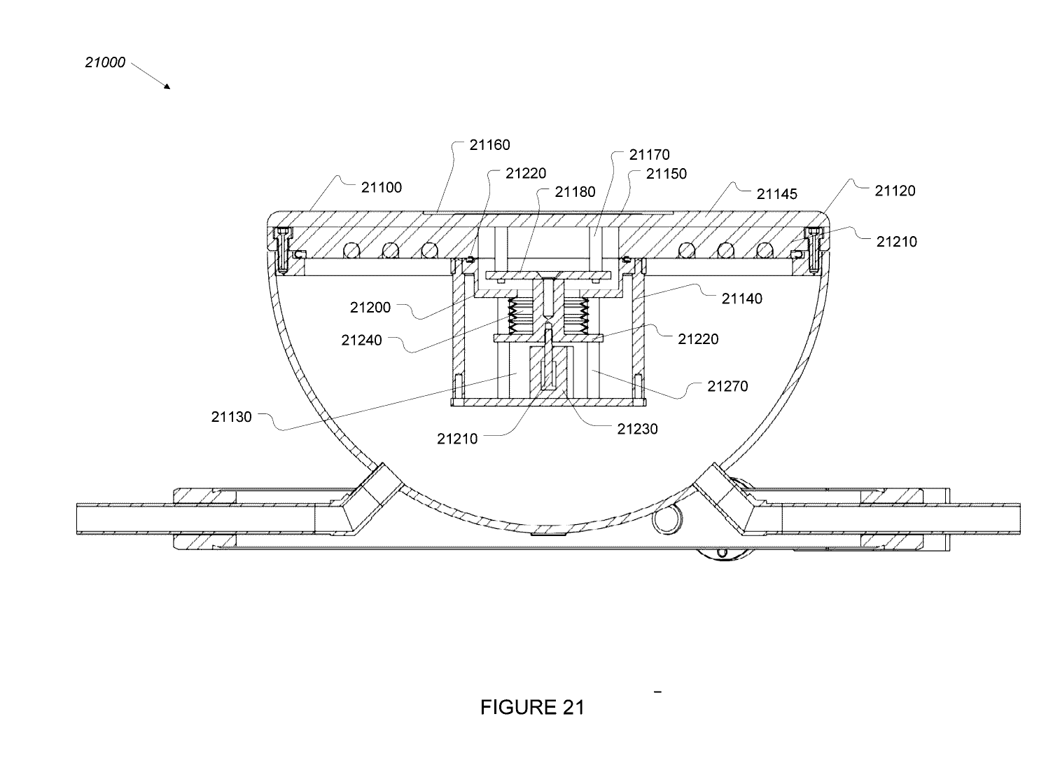

Referring now to FIGS. 21 and 22, a heated substrate support chuck (21000) includes a substrate lifting mechanism (21130) configured to raise and lower a movable substrate support element (21150) with respect to the substrate support surface (21100). The lifting mechanism (21130) is housed inside the substrate support chuck (21000) and hung by brackets (21140) from an underside if a middle circular plate (21210). A circular substrate support element (21150) is disposed outside the substrate support chuck (21000) approximately centered with respect to the circular substrate support surface (21100). Preferably, a diameter of the circular substrate support element (21150) is smaller than a diameter of the smallest substrates that will be coated in the gas deposition chamber (20000). A circular recess (21160) formed at the center of the circular substrate support surface (21100) receives the substrate support element (21150) therein with a top surface of the substrate support element (21150) substantially flush with or below the substrate support surface (21100). A diameter of the circular recess (21160) is also preferably smaller than the smallest substrates that will be coated in the gas deposition chamber (20000). During a deposition coating cycle, a circular substrate such as a silicon wafer, or the like, is centered on the on the circular substrate support surface (21100) and the support element (21140) is parked in the circular recess (21160). Preferably, the substrate being coated is only in contact with the substrate support surface (21110) during a coating cycle.

The lifting mechanism includes two or more lift pins (21170) attached to a lift plate (21180) at a bottom end of the lift pins. The lift pins (21170) each movably pass through corresponding holes that pass through a top circular plate (21145) and are attached to the circular substrate support element (21150) at top ends thereof. The lift plate (21180) is circular and is housed in a gas tight chamber formed by a chamber housing (21200) that attaches to a circular middle plate (21210) with a circular o-ring or c-ring (21220) is disposed to gas seal the chamber housing (21200) with respect to the middle plate (21210). A second o-ring or c-ring (21260) is disposed to gas seal the interface between the middle plate (21210) and the hemispherical bottom portion (21110).

A transfer bracket (21220) is disposed between an actuator element (21230) and the lift plate (21180) and movably passes through a bottom wall of the chamber housing (21200). Movement of the transfer bracket (21220) may be movably guided along stationary rods (21270) that engage with the transfer bracket. A bellows (21240) is disposed between the chamber housing (21200) and the transfer bracket (21220) to gas seal the chamber housing where the transfer bracket (21220) passes through the chamber housing (21200).

In response to an electrical command, pneumatic pulse, or the like, the actuator (21230) lifts an actuator plunger (21210) upward and holds the actuator plunger (21210) in a lifted position. The upward motion of the actuator plunger (21210) is transferred to the lift pins (21170), which move through the top plate (21145) lifting the circular substrate support element (21150) out of the circular recess (21160). The substrate support element therefore lifts the substrate from the substrate support surface (21100) and supports the substrate in a load/unload position resting on the circular substrate support element (21150). FIG. 22 shows a sectioned isometric view of the gas deposition chamber (20000) with the circular substrate support element (21150) shown in the lifted or load/unload position. In the load/unload position, the substrate is lifted sufficiently above the substrate support surface (21100) to allow a substrate handler or manipulator to make contact with a bottom or uncoated side of the substrate and lift or otherwise guide the substrate out of the gas deposition chamber (20000) through the load port (20140). Thereafter, the substrate handler or manipulator loads an uncoated substrate onto the circular substrate support element (21150). Thereafter the manipulator is withdrawn from the gas deposition chamber through the load port (20140). To initiate a new coating cycle, the actuator plunger (21210) is lowered to its bottom position to lower the uncoated substrate into contact with the substrate support surface (21100) and the shuttle mechanism (20180) is actuated to lower the load port cover (21070) in place over the substrate load port aperture (20150).

It will also be recognized by those skilled in the art that, while the invention has been described above in terms of preferred embodiments, it is not limited thereto. Various features and aspects of the above described invention may be used individually or jointly. Further, although the invention has been described in the context of its implementation in a particular environment, and for particular applications, those skilled in the art will recognize that its usefulness is not limited thereto and that the present invention can be beneficially utilized in any number of environments and implementations where it is desirable to coat objects with thin layers of solid material by gas deposition processes. Accordingly, the claims set forth below should be construed in view of the full breadth and spirit of the invention as disclosed herein.

What is claimed is:

1. A method for coating a substrate with a solid material layer comprising the steps of:
supporting the substrate on substrate support surface disposed in a substantially constant volume middle portion of a hollow gas deposition volume;
introducing a first process gas into a volume expanding top portion of the hollow gas deposition volume and allowing the first process gas to expand in volume prior to impinging surfaces of the substrate;
drawing the process gas out of the hollow deposition chamber through a exit port wherein the exit port is positioned opposed to the volume expanding top portion of the hollow gas deposition volume;
removing substantially all of the first process gas from the hollow gas deposition volume while delivering an flow of inert gas into the hollow gas deposition volume;
introducing a second process gas into the volume expanding top portion of the hollow gas deposition volume and allowing the second process gas to expand in volume prior to impinging surfaces of the substrate; and,
removing substantially all of the second process gas from the hollow gas deposition volume while delivering a flow of inert gas into the hollow gas deposition volume.

2. The method of claim 1 wherein one of the first and the second process gases comprises a charged plasma gas.

3. The method of claim 2 wherein another of the first and the second process gases comprises a precursor gas.

4. The method of claim 3 wherein the hollow gas deposition volume further comprising a volume reducing bottom portion reducing the volume of the hollow deposition chamber between the substantially constant volume middle portion and the exit port further comprising step of reducing the volume of each of the first and the second process gasses as they pass between the substrate support surface and the exit port.

5. The method of claim 4 further comprising the step of preventing eddy current formation proximate to the substrate support surface by forming the substrate surface on a drag reducing aerodynamically shaped substrate support chuck.
